(19) United States
(12) Patent Application Publication
(10) Pub. No.: US 2025/0040200 A1
(43) Pub. Date: Jan. 30, 2025

(54) SEMICONDUCTOR STRUCTURE AND METHOD FOR FORMING THE SAME

(71) Applicant: Taiwan Semiconductor Manufacturing Company, Ltd., Hsinchu (TW)

(72) Inventors: Yu-Sheng CHEN, New Taipei City (TW); Pang-Hsuan LIU, Taoyuan City (TW); Shu-Hui WANG, Hsinchu City (TW); Ju-Li HUANG, Nantou County (TW); Jeng-Ya YEH, New Taipei City (TW)

(21) Appl. No.: 18/361,226

(22) Filed: Jul. 28, 2023

(51) Int. Cl. H01L 29/06; H01L 21/8238; H01L 27/092; H01L 29/423; H01L 29/66; H01L 29/775; H01L 29/786

(52) U.S. Cl. CPC H01L 29/0673; H01L 21/823807; H01L 27/092; H01L 29/42392; H01L 29/66439; H01L 29/66545; H01L 29/775; H01L 29/78696

(57) ABSTRACT

A method for forming a semiconductor structure is provided. The method includes forming a first nanostructure and a second nanostructure over a substrate, forming a first interfacial layer on the first nanostructure and a second interfacial layer on the second nanostructure, forming a first gate dielectric layer on the first interfacial layer and a second gate dielectric layer on the second interfacial layer, forming a patterned mask layer on the second gate dielectric layer while exposing the first gate dielectric layer, and driving nitrogen into the first interfacial layer, thereby forming a nitrogen-doped interfacial layer.

### BACKGROUND

The electronics industry is experiencing an ever-increasing demand for smaller and faster electronic devices which are simultaneously able to support a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). One such multi-gate device that has been introduced is the gate-all around transistor (GAA). The GAA device gets its name from the gate structure, which can extend around the channel region and provide access to the channel on two or four sides. GAA devices are compatible with conventional complementary metal-oxide-semiconductor (CMOS) processes, and their structure allows them to be aggressively scaled-down while maintaining gate control and mitigating SCEs. In conventional processes, GAA devices provide a channel in a silicon nanowire. However, integration of fabrication of the GAA features around the nanowire can be challenging. For example, while current methods have been satisfactory in many respects, continued improvements are still needed.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a perspective view of a semiconductor structure, in accordance with some embodiments of the disclosure.

FIGS. 2A-1 through 2D-2 are cross-sectional views illustrating the formation of a semiconductor structure at various intermediate stages, in accordance with some embodiments of the disclosure.

FIGS. 3A through 3L are cross-sectional views illustrating an incorporation of dopants into an interfacial layer and the formation of final gate stacks at various intermediate stages, in accordance with some embodiments of the disclosure.

FIG. 4 is a schematic view exhibiting that distributions of the nitrogen concentrations vary with location, in accordance with some embodiments of the disclosure.

FIGS. 5A through 5D are cross-sectional views illustrating an incorporation of dopants into an interfacial layer and the formation of final gate stacks at various intermediate stages, in accordance with some embodiments of the disclosure.

FIGS. 6A through 6H are cross-sectional views illustrating an incorporation of dopants into an interfacial layer and the formation of final gate stacks at various intermediate stages, in accordance with some embodiments of the disclosure.

FIGS. 7A and 7B are cross-sectional views illustrating an incorporation of dopants into an interfacial layer and the formation of final gate stacks at various intermediate stages, in accordance with some embodiments of the disclosure.

FIG. 8 illustrate a portion of a semiconductor structure, in accordance with some embodiments of the disclosure.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of a semiconductor structure are provided. The aspect of the present disclosure is directed to a semiconductor structure having various devices with different threshold voltages. The semiconductor structure includes an n-type transistor and a p-type transistor. An incorporation of nitrogen is performed to drive nitrogen into the interfacial layer of the n-type transistor, thereby thinning down the capacitance equivalent thickness of the n-type transistor. The interfacial layer of the p-type transistor P1 remains undoped. Therefore, the performance (e.g., DC performance and RO performance) of the resulting semiconductor device may improve.

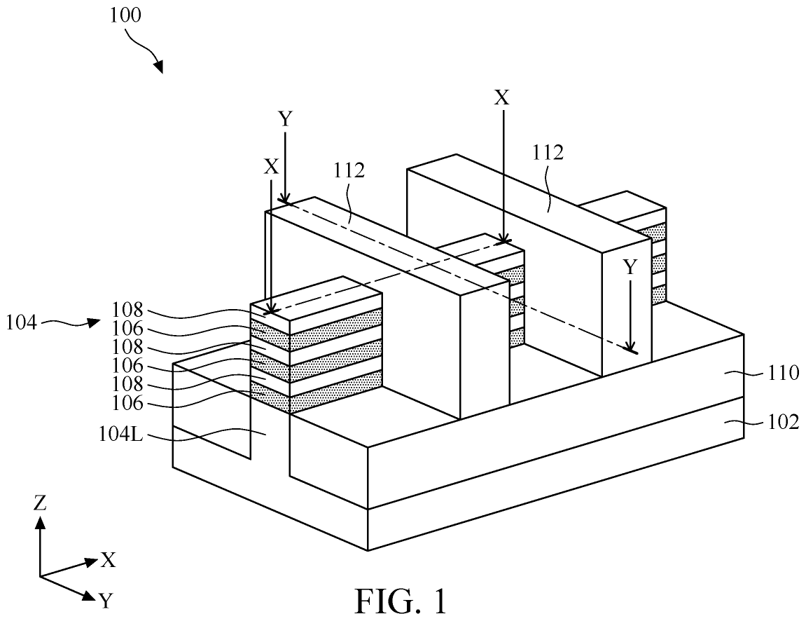

FIG. 1 is a perspective view of a semiconductor structure 100, in accordance with some embodiments of the disclosure.

The semiconductor structure 100 includes a substrate 102 and a fin structure 104 over the substrate 102, as shown in FIG. 1, in accordance with some embodiments. The fin structure 104 is the active region of the semiconductor structure 100, in accordance with some embodiments. The fin structure 104 includes a lower fin element 104L formed from the substrate 102, in accordance with some embodiments. The lower fin element 104L is surrounded by an isolation structure 110, in accordance with some embodiments. The fin structure 104 further includes an upper fin element formed from an epitaxial stack including alternating first semiconductor layers 106 and second semiconductor layers 108, in accordance with some embodiments. The second semiconductor layers 108 will form nanostructures (e.g., nanowires or nanosheets) and serve as the channel for the resulting semiconductor devices, in accordance with some embodiments.

For a better understanding of the semiconductor structure 100, the X-Y-Z coordinate reference is provided in the figures of the present disclosure. The X-axis and the Y-axis are generally orientated along the lateral (or horizontal) directions that are parallel to the main surface of the substrate 102. The Y-axis is transverse (e.g., substantially perpendicular) to the X-axis. The Z-axis is generally oriented along the vertical direction that is perpendicular to the main surface of the substrate 102 (or the X-Y plane).

The fin structure 104 extends in the X direction, in accordance with some embodiments. That is, the fin structure 104 has a longitudinal axis parallel to the X direction, in accordance with some embodiments. The X direction may also be referred to as the channel-extending direction. The current of the resulting semiconductor device (i.e., nanostructure transistor) flows in the X direction through the channel. The fin structure 104 is defined as several channel regions and several source/drain regions, where the channel regions and the source/drain regions are alternately arranged, in accordance with some embodiments. In this disclosure, a source/drain refers to a source and/or a drain. It is noted that in the present disclosure, a source and a drain are interchangeably used and the structures thereof are substantially the same.

Gate structures 112 are formed with longitudinal axes parallel to the Y direction and extending across and/or surrounding the channel regions of the fin structure 104, in accordance with some embodiments. The source/drain regions of the fin structure 104 are exposed from the gate structure 112, in accordance with some embodiments. The Y direction may also be referred to as a gate-extending direction.

FIG. 1 further illustrates reference cross-sections that are used in later figures. Cross-section X-X is in a plane parallel to the longitudinal axis (X direction) of the fin structure 104 and through the fin structure 104, in accordance with some embodiments. Cross-section Y-Y is in a plane parallel to the longitudinal axis (Y direction) of a gate structure 112 and through the gate structure or gate stack (i.e., across the channel region of the fin structure 104), in accordance with some embodiments.

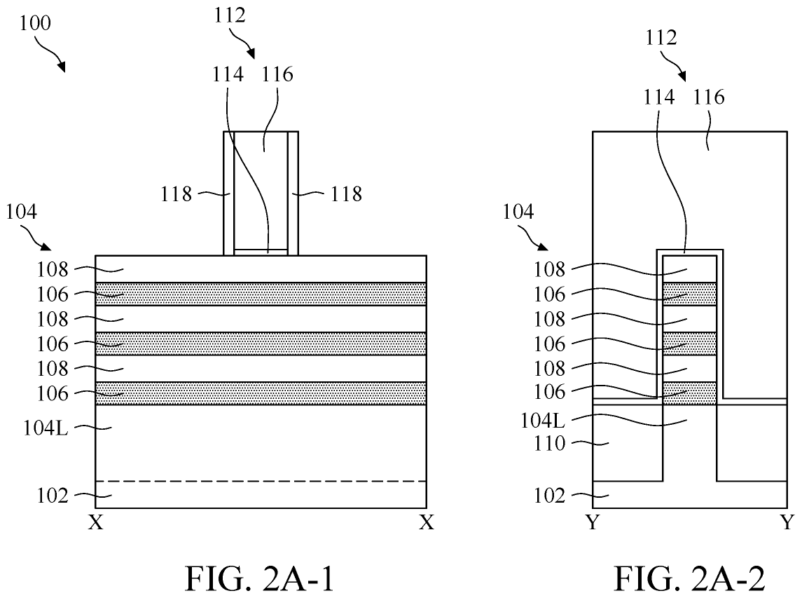

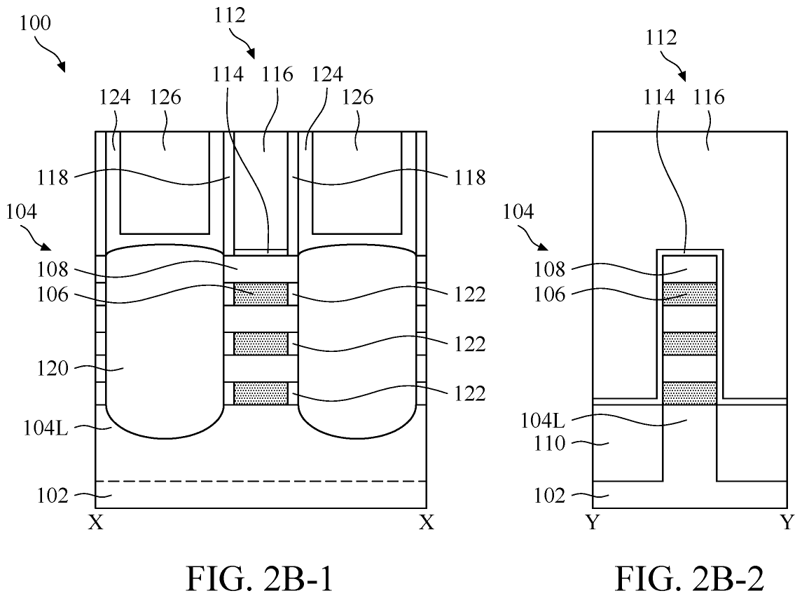

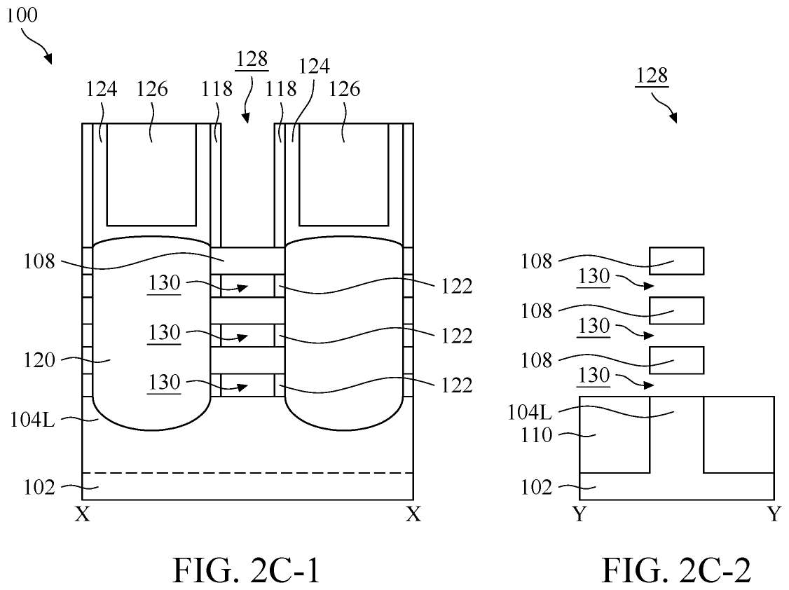

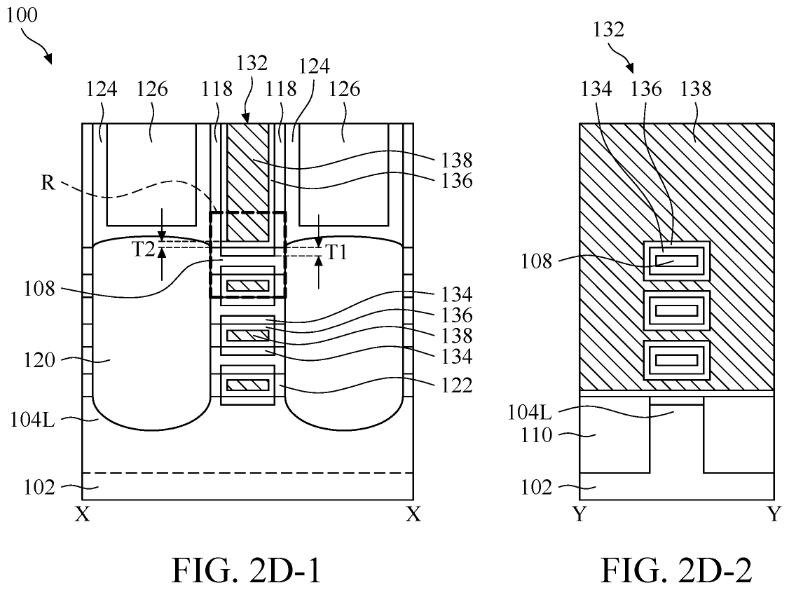

FIGS. 2A-1 through 2D-2 are cross-sectional views illustrating the formation of a semiconductor structure 100 at various intermediate stages, in accordance with some embodiments of the disclosure.

FIGS. 2A-1 and 2A-2 illustrate a semiconductor structure 100 after the formation of an active region 104, an isolation structure 110, a dummy gate structure 112 and gate spacer layers 118, in accordance with some embodiments. FIGS. 2A-1 and 2A-2 correspond to line X-X and line Y-Y of FIG. 1, respectively.

The semiconductor structure 100 includes a substrate 102, an active region 104 and an isolation structure 110 over the substrate 102, and a dummy gate structure 112 over the active region 104 and the isolation structure 110, as shown in FIGS. 2A-1 and 2A-2, in accordance with some embodiments.

The substrate 102 may be a portion of a semiconductor wafer, a semiconductor chip (or die), and the like. In some embodiments, the substrate 102 is a silicon substrate. In some embodiments, the substrate 102 includes an elementary semiconductor such as germanium; a compound semiconductor such as gallium nitride (GaN), silicon carbide (SiC), gallium arsenide (GaAs), gallium phosphide (GaP), indium phosphide (InP), indium arsenide (InAs), and/or indium antimonide (InSb); an alloy semiconductor such as SiGe, GaAsP, AlInAs, AlGaAs, GaInAs, GaInP, and/or GaInAsP; or a combination thereof. Furthermore, the substrate 102 may optionally include an epitaxial layer (epi-layer), may be strained for performance enhancement, may include a silicon-on-insulator (SOI) structure, and/or have other suitable enhancement features.

In some embodiments, the active region 104 extends in the X direction. That is, the active region 104 has a longitudinal axis parallel to the X direction, in accordance with some embodiments. The formation of the active region 104 includes forming an epitaxial stack over the substrate 102 using an epitaxial growth process, in accordance with some embodiments. The epitaxial stack includes alternating first semiconductor layers 106 and second semiconductor layers 108, in accordance with some embodiments. The epitaxial growth process may be molecular beam epitaxy (MBE), metal organic chemical vapor deposition (MOCVD), or vapor phase epitaxy (VPE), or another suitable technique.

In some embodiments, the first semiconductor layers 106 are made of a first semiconductor material and the second semiconductor layers 108 are made of a second semiconductor material. The first semiconductor material used for the first semiconductor layers 106 has a different lattice constant than the second semiconductor material used for the second semiconductor layers 108, in accordance with some embodiments. In some embodiments, the first semiconductor material and the second semiconductor material may have different oxidation rates and/or etching selectivity. In some embodiments, the first semiconductor layers 106 are made of SiGe, where the percentage of germanium (Ge) in the SiGe is in a range from about 20 atomic % to about 50 atomic %, and the second semiconductor layers 108 are made of pure or substantially pure silicon. In some embodiments, the first semiconductor layers 106 are Si₁₋ₓGeₓ, where x is more than about 0.3, or Ge (x=1.0) and the second semiconductor layers 108 are Si or Si_{1-y}Ge_{y}, where y is less than about 0.4, and x>y.

The first semiconductor layers 106 are configured as sacrificial layers and will be removed to form gaps to accommodate gate materials, and the second semiconductor layers 108 will form nanostructures (e.g., nanowires or nanosheets) that laterally extend between source/drain features and serve as the channel layers for the resulting semiconductor devices (such as nanostructure transistors), in accordance with some embodiments.

The formation of the active region 104 further includes patterning the epitaxial stack and underlying substrate 102 using photolithography and etching processes, thereby forming trenches and the active region 104 protruding from between trenches, in accordance with some embodiments. The portion of substrate 102 protruding from between the trenches serves as a lower fin element 104L of the active region 104, in accordance with some embodiments. A remainder of the epitaxial stack (including the first semiconductor layers 106 and the second semiconductor layers 108) serves as an upper fin element of the active region 104, in accordance with some embodiments. In some embodiments, the active region 104 is the fin structure 104 as shown in FIG. 1.

In some embodiments, the thickness of each of the first semiconductor layers 106 is in a range from about 6 nm to about 15 nm. In some embodiments, the thickness of each of the second semiconductor layers 108 is in a range from about 4 nm to about 8 nm. The thickness of the second semiconductor layers 108 may be greater than, equal to, or less than the first semiconductor layers 106, depending on the amount of gate materials to be filled in spaces where the first semiconductor layers 106 are removed. Although three first semiconductor layers 106 and three second semiconductor layers 108 are shown in FIGS. 2A-1 and 2A-2, the number is not limited to three, and can be two or four, and is less than 10.

An isolation structure 110 is formed to surround the lower fin element 104L of the active region 104, as shown in FIG. 2A-2, in accordance with some embodiments. The isolation structure 110 is configured to electrically isolate neighboring active regions from each other and is also referred to as shallow trench isolation (STI) feature, in accordance with some embodiments. The bottom surface of the isolation structure 110 is illustrated as a dashed line in FIG. 2A-1.

The formation of the isolation structure 110 includes forming an insulating material to overfill the trenches, in accordance with some embodiments. In some embodiments, the insulating material is made of silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof. In some embodiments, the insulating material is deposited using CVD (such as flowable CVD (FCVD), low-pressure CVD (LPCVD), plasma-enhanced CVD (PECVD), high density plasma CVD (HDP-CVD), or high aspect ratio process (HARP)), atomic layer deposition (ALD), another suitable technique, or a combination thereof.

A planarization process is performed on the insulating material to remove a portion of the insulating material above the active region 104, in accordance with some embodiments. The planarization may be chemical mechanical polishing (CMP), an etching back process, or a combination thereof. The insulating material is then recessed by an etching process (such as dry plasma etching and/or wet chemical etching) until the upper fin element of the active region 104 are exposed, in accordance with some embodiments. The recessed insulating material serves as the isolation structure 110, in accordance with some embodiments.

A dummy gate structure 112 is formed across the active region 104, as shown in FIGS. 2A-1 and 2A-2. The dummy gate structure 112 is configured as a sacrificial structure and will be replaced with a final gate stack, in accordance with some embodiments. In some embodiments, the dummy gate structure 112 extends in the Y direction. That is, the dummy gate structure 112 has a longitudinal axis parallel to the Y direction, in accordance with some embodiments. The dummy gate structure 112 surrounds the channel region of the active region 104, in accordance with some embodiments. The dummy gate structure 112 may be similar to the gate structure 112 shown in FIG. 1.

The dummy gate structure 112 includes a dummy gate dielectric layer 114 and a dummy gate electrode layer 116 over the dummy gate dielectric layer 114, in accordance with some embodiments. In some embodiments, the dummy gate dielectric layer 114 is conformally formed along the upper fin elements of the active region 104 and the isolation structure 110. In some embodiments, the dummy gate dielectric layer 114 is made of one or more dielectric materials, such as silicon oxide (SiO), silicon nitride (SiN), silicon oxynitride (SiON), HfO₂, HfZrO, HfSiO, HTiO, HfAlO. In some embodiments, the dielectric material is deposited using ALD, CVD, thermal oxidation, physical vapor deposition (PVD), another suitable technique, or a combination thereof. In some embodiments, the dummy gate electrode layer 116 is made of semiconductor material such as polysilicon or poly-silicon germanium. In some embodiments, the material for the dummy gate electrode layer 116 is deposited using CVD, ALD, another suitable technique, or a combination thereof.

In some embodiments, the formation of the dummy gate structure 112 includes globally and conformally depositing a dielectric material for the dummy gate dielectric layer 114 over the semiconductor structure 100, depositing a material for the dummy gate electrode layer 116 over the dielectric material, planarizing the material for the dummy gate electrode layer 116, and patterning the material for the dummy gate electrode layer 116 and the dielectric material into the dummy gate structure 112. The patterning process includes forming a patterned hard mask layer (not shown) over the material for the dummy gate electrode layer 116, in accordance with some embodiments. The hard mask layer corresponds to and overlaps the channel region of the active region 104, in accordance with some embodiments. The materials for the dummy gate dielectric layer 114 and the dummy gate electrode layer 116, uncovered by the patterned hard mask layer, are etched away until the source/drain regions of the active region 104 are exposed, in accordance with some embodiments.

Gate spacer layers 118 are formed over the semiconductor structure 100, as shown in FIG. 2A-1, in accordance with some embodiments. The gate spacer layers 118 extend along, and cover, the opposite sides of the dummy gate structure 112, in accordance with some embodiments. The gate spacer layers 118 are used to offset the subsequently formed source/drain features and separate the source/drain features from the gate structure, in accordance with some embodiments. The gate spacer layers 118 may be also referred to as top spacer layers.

In some embodiments, the gate spacer layers 118 are made of a dielectric material, such as silicon oxide (SiO₂), silicon nitride (SiN), silicon oxynitride (SiON), silicon carbide (SiC), oxygen-doped silicon carbide (SiC:O), oxygen-doped silicon carbonitride (Si(O)CN), or a combination thereof, or a combination thereof. In some embodiments, the gate spacer layers 118 are made of low-k dielectric materials. For example, the dielectric constant (k) value of the gate spacer layers 118 may be lower than a k-value of silicon oxide (SiO), such as lower than 4.2, equal to or lower than about 3.9, such as in a range from about 3.5 to about 3.9.

In some embodiments, the formation of the gate spacer layers 118 includes conformally depositing dielectric materials for the gate spacer layers 118 over the semiconductor structure 100 followed by an anisotropic etching process (such as dry plasma etching). In some embodiments, the deposition process includes ALD, CVD (such as PECVD, LPCVD or HARP), another suitable technique, or a combination thereof. Vertical portions of the dielectric material left on the sidewalls of the dummy gate structure 112 serve as the gate spacer layers 118, in accordance with some embodiments.

FIGS. 2B-1 and 2B-2 illustrate a semiconductor structure 100 after the formation of source/drain features 120, inner spacer layers 122, a contact etching stop layer (CESL) 124 and an interlayer dielectric layer 126, in accordance with some embodiments. FIGS. 2B-1 and 2B-2 correspond to line X-X and line Y-Y of FIG. 1, respectively.

Source/drain features 120 are formed in and/or over the source/drain regions of the active region 104, as shown in FIG. 2B-1, in accordance with some embodiments. The source/drain features 120 are formed on opposite sides of the dummy gate structure 112, in accordance with some embodiments. The formation of the source/drain features 120 includes recessing the source/drain regions of the active region 104 using the dummy gate structure 112 and the gate spacer layers 118 as a mask to form source/drain recesses on opposite sides of the dummy gate structure 112, in accordance with some embodiments. The recessing process may be an anisotropic etching process such as dry plasma etching, an isotropic etching process such as dry chemical etching, remote plasma etching or wet chemical etching, or a combination thereof.

An etching process is performed to laterally recess, from the source/drain recesses, the first semiconductor layers 106 of the active region 104, thereby forming notches, and then inner spacer layers 122 are formed in the notches, as shown in FIG. 2B-1, in accordance with some embodiments. The inner spacer layers 122 are formed to abut the recessed side surfaces of the first semiconductor layers 106, in accordance with some embodiments. In some embodiments, the inner spacer layers 122 are located between adjacent second semiconductor layers 108 and between the lowermost second semiconductor layer 108 and the lower fin element 104L. In some embodiments, the inner spacer layers 122 extend directly below the gate spacer layers 118, in accordance with some embodiments.

The inner spacer layers 122 may avoid the source/drain features 120 and the gate stack from being in direct contact and are configured to reduce the parasitic capacitance between the gate stack and the source/drain features (i.e., Cgs and Cgd), in accordance with some embodiments. In some embodiments, the inner spacer layers 122 are made of dielectric material, such as silicon oxide (SiO₂), silicon nitride (SiN), silicon carbide (SiC), silicon oxynitride (SiON), silicon carbon nitride (SiCN), silicon oxycarbonitride (SiOCN), and/or oxygen-doped silicon carbonitride (Si(O)CN). In some embodiments, the inner spacer layers 122 are made of low-k dielectric materials. For example, the dielectric constant (k) value of the inner spacer layers 122 may be lower than a k-value of silicon oxide (SiO), such as lower than 4.2, equal to or lower than about 3.9, such as in a range from about 3.5 to about 3.9.

In some embodiments, the inner spacer layers 122 are formed by depositing a dielectric material for the inner spacer layers 122 over the semiconductor structure 100 to fill the notches, and then etching back the dielectric material to remove the dielectric material outside the notches. Portions of the dielectric material left in the notches serve as the inner spacer layers 122, in accordance with some embodiments. In some embodiments, the deposition process includes ALD, CVD (such as PECVD, LPCVD or HARP), another suitable technique, or a combination thereof. In some embodiments, the etching back process includes an anisotropic etching process such as dry plasma etching, an isotropic etching process such as dry chemical etching, remote plasma etching or wet chemical etching, or a combination thereof.

Afterward, the source/drain features 120 are grown in the source/drain recesses on the exposed surfaces of the second semiconductor layers 108 and the lower fin element 104L, as shown in FIG. 2B-1, in accordance with some embodiments. In some embodiments, the source/drain features 120 are made of any suitable semiconductor material for an n-type semiconductor device and a p-type semiconductor device, such as Ge, Si, GaAs, AlGaAs, SiGe, GaAsP, SiP, SiC, SiCP, or a combination thereof. In some embodiments, the source/drain features 120 are in-situ doped during the epitaxial growth process.

In some embodiments wherein the active region 104 is to be formed as an n-type device (such as an n-channel nanostructure transistor), the source/drain features 120 are made of semiconductor material such as SiP, SiAs, SiCP, SiC, Si, GaAs, another suitable semiconductor material, or a combination thereof. In some embodiments, the source/drain features 120 are doped with the n-type dopant during the epitaxial growth process. For example, the n-type dopant may be phosphorous (P) or arsenic (As). For example, the source/drain features 120 may be the epitaxially grown Si doped with phosphorous to form silicon:phosphor (Si:P) source/drain features and/or arsenic to form silicon:arsenic (Si:As) source/drain feature.

In some embodiments wherein the active region 104 is to be formed as a p-type device (such as a p-channel nanostructure device), the source/drain features 120 are made of semiconductor material such as SiGe, Si, GaAs, another suitable semiconductor material, or a combination thereof. In some embodiments, the source/drain features 120 are doped with the p-type dopant during the epitaxial growth process. For example, the p-type dopant may be boron (B) or BF₂. For example, the source/drain features 120 may be the epitaxially grown SiGe doped with boron (B) to form silicon germanium:boron (SiGe:B) source/drain feature.

A contact etching stop layer 124 is formed over the semiconductor structure 100, as shown in FIG. 2B-1, in accordance with some embodiments. The contact etching stop layer 124 extends along, and covers, the surfaces of the source/drain features 120 and the sidewalls of the gate spacer layers 118, in accordance with some embodiments.

In some embodiments, the contact etching stop layer 124 is made of a dielectric material, such as silicon oxide (SiO₂), silicon nitride (SiN), silicon oxynitride (SiON), silicon oxynitride (SiOC), silicon carbide (SiC), oxygen-doped silicon carbide (SiC:O), oxygen-doped silicon carbonitride (Si(O)CN), or a combination thereof. In some embodiments, a dielectric material for the contact etching stop layer 124 is globally and conformally deposited over the semiconductor structure 100 using CVD (such as LPCVD, PECVD, HDP-CVD, HARP, and FCVD), ALD, another suitable method, or a combination thereof.

An interlayer dielectric layer 126 is formed over the contact etching stop layer 124, as shown in FIG. 2B-1, in accordance with some embodiments. In some embodiments, the interlayer dielectric layer 126 is made of a dielectric material, such as un-doped silicate glass (USG), or doped silicon oxide such as borophosphosilicate glass (BPSG), fluoride-doped silicate glass (FSG), phosphosilicate glass (PSG), borosilicate glass (BSG), and/or another suitable dielectric material. In some embodiments, a dielectric material for the interlayer dielectric layer 126 is deposited using such as CVD (such as HDP-CVD, PECVD, HARP or FCVD), another suitable technique, or a combination thereof.

In some embodiments, the interlayer dielectric layer 126 and the contact etching stop layer 124 have a great difference in etching selectivity. In some embodiments, the interlayer dielectric layer 126 is made of an oxide (such as silicon oxide) and the contact etching stop layer 124 is made of a nitrogen-containing dielectric (such as silicon nitride or silicon oxynitride).

Afterward, the dielectric materials for the contact etching stop layer 124 and the interlayer dielectric layer 126 above the upper surfaces of the dummy gate electrode layer 116 are removed using such as CMP until the upper surface of the dummy gate structure 112 is exposed, in accordance with some embodiments. In some embodiments, the upper surface of the interlayer dielectric layer 126 is substantially coplanar with the upper surface of the dummy gate electrode layer 116.

FIGS. 2C-1 and 2C-2 illustrate a semiconductor structure 100 after the formation of a gate trench 128 and gaps 130, in accordance with some embodiments. FIGS. 2C-1 and 2C-2 correspond to line X-X and line Y-Y of FIG. 1, respectively.

The dummy gate structure 112 is removed using etching process to form gate trench 128 between the gate spacer layers 118, as shown in FIGS. 2C-1 and 2C-2, in accordance with some embodiments. In some embodiments, the gate trench 128 exposes the channel region of the active region 104. In some embodiments, the gate trench 128 further exposes the sidewalls of the gate spacer layers 118 facing the channel region. In some embodiments, the etching process includes one or more etching processes. For example, when the dummy gate electrode layer 116 is made of polysilicon, a wet etchant such as a tetramethylammonium hydroxide (TMAH) solution may be used to selectively remove the dummy gate electrode layer 116. For example, the dummy gate dielectric layer 114 may be thereafter removed using a plasma dry etching, a dry chemical etching, and/or a wet etching.

Afterward, an etching process is performed to remove the first semiconductor layers 106 of the active region 104 to form gaps 130, as shown in FIGS. 2C-1 and 2C-2, in accordance with some embodiments. The inner spacer layers 122 may be used as an etching stop layer in the etching process, which may protect the source/drain features 120 from being damaged. In some embodiments, the etching process includes a selective wet etching process, such as APM (e.g., ammonia hydroxide-hydrogen peroxide-water mixture) etching process. In some embodiments, the wet etching process uses etchants such as ammonium hydroxide (NH₄OH), TMAH, ethylenediamine pyrocatechol (EDP), and/or potassium hydroxide (KOH) solutions.

The gaps 130 are formed between adjacent second semiconductor layers 108 and between the lowermost second semiconductor layer 108 and the lower fin element 104L, in accordance with some embodiments. In some embodiments, the gaps 130 also expose the sidewalls of the inner spacer layers 122 facing the channel region.

After the one or more etching processes, the four main surfaces of the second semiconductor layers 108 are exposed, in accordance with some embodiments. The exposed second semiconductor layers 108 are vertically stacked and spaced apart from one other and form a set of nanostructures 108, in accordance with some embodiments. As the term is used herein, “nanostructures” refers to the semiconductor layers with cylindrical shape, bar shaped and/or sheet shape. The nanostructures 108 function as channels of the resulting semiconductor devices (e.g., nanostructure transistors such as GAA transistors), in accordance with some embodiments.

FIGS. 2D-1 and 2D-2 illustrate a semiconductor structure 100 after the formation of a final gate stack 132, in accordance with some embodiments. FIGS. 2D-1 and 2D-2 correspond to line X-X and line Y-Y of FIG. 1, respectively.

A final gate stack 132 is formed in the gate trench 128 and gaps 130, thereby wrapping around the nanostructures 108, as shown in FIGS. 2D-1 and 2D-2, in accordance with some embodiments. In some embodiments, the final gate stack 132 extends in the Y direction. That is, the final gate stack 132 has a longitudinal axis parallel to the Y direction, in accordance with some embodiments. In some embodiments, the final gate stack 132 includes an interfacial layer 134, a gate dielectric layer 136 and a gate electrode layer 138, as shown in FIGS. 2D-1 and 2D-2, in accordance with some embodiments.

The interfacial layer 134 is formed on the exposed surfaces of the nanostructures 108 and the exposed upper surfaces of the lower fin element 104L, in accordance with some embodiments. The interfacial layer 134 wraps around and are in direct contact with the nanostructures 108, in accordance with some embodiments. In some embodiments, the interfacial layer 134 is made of a chemically formed silicon oxide. In some embodiments, the interfacial layer 134 is nitrogen-doped silicon oxide.

In some embodiments, the interfacial layer 134 is formed using one or more cleaning processes such as including ozone (03), ammonia hydroxide-hydrogen peroxide-water mixture, and/or hydrochloric acid-hydrogen peroxide-water mixture. Semiconductor material from the surface portions of the nanostructures 108 and the lower fin element 104L is oxidized to form the interfacial layer 134 in the cleaning processes, in accordance with some embodiments. In some embodiments, the interfacial layer 134 is silicon oxide and has a dielectric constant of approximately 3.9. In some embodiments, the interfacial layer 134 has a thickness T1 in a range from about 5 angstroms (Å) to about 15 Å.

The gate dielectric layer 136 is formed conformally along the interfacial layer 134 to wrap around the nanostructures 108, in accordance with some embodiments. The gate dielectric layer 136 is further formed along the upper surface of the isolation structure 110, in accordance with some embodiments. The gate dielectric layer 136 is also conformally formed along the sidewalls of the gate spacer layers 118 facing the channel region, in accordance with some embodiments. The gate dielectric layer 136 is also conformally formed along the sidewalls of the inner spacer layers 122 facing the channel region, in accordance with some embodiments.

The gate dielectric layer 136 may include one or more high-k dielectric layers. In some embodiments, the high-k dielectric layers are dielectric material with high dielectric constant (k value), for example, greater than 9, such as greater than 13, such as greater than 20. In some embodiments, the high-k dielectric layer includes hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, (Ba,Sr)TiO₃ (BST), a multilayer thereof, a combination thereof, or another suitable material. The high-k dielectric layer may be deposited using ALD, PVD, CVD, and/or another suitable technique. In some embodiments, the gate dielectric layer 136 has a thickness T2 in a range from about 0.5 nm to about 4 nm.

After the gate dielectric layer 136 is formed, one or more dopant incorporation processes may be performed on the semiconductor structure 100, thereby doping or incorporating dopants (e.g., nitrogen, fluorine, oxygen, dipole elements such as aluminum, lanthanum, magnesium, titanium, zirconium, and/or another suitable dopant) into the gate dielectric layer 136 and/or the interfacial layer 134, in accordance with some embodiments.

For example, variations of the dopant concentrations can lead to changes in the crystallographic structure of the gate dielectric layer (e.g., hafnium-based high-k dielectric layer), and form and/or boost the electric dipoles (e.g., n-type dipole and/or p-type dipole) in the gate dielectric layer 136 or at the interfaces between the gate dielectric layers and subsequently formed work function layers, which can tune spontaneous polarization and internal bias fields and result in variations of the threshold voltages of the resulting semiconductor devices.

Furthermore, the incorporation of dopants into the interfacial layer 134 can adjust the capacitance equivalent thickness (CET) of the resulting semiconductor device, which can also tune the threshold voltages of the resulting semiconductor devices, and/or enhance the gate control capability over the channel.

The metal gate electrode layer 138 is formed to fill remainders of the gate trench 128 and gaps 130, in accordance with some embodiments. In some embodiments, the metal gate electrode layer 138 is made of more than one conductive material, such as a metal, metal alloy, conductive metal oxide and/or metal nitride, another suitable conductive material, or a combination thereof. For example, the gate electrode layer 138 is TIN, TaN, TiAl, TiAlN, TaAl, TaAlN, TaAlC, TaCN, WNC, Co, Pt, W, Ti, Ag, Al, TaC, TaSiN, Mn, Zr, Ru, Mo, WN, Cu, W, Re, Ir, Ni, another suitable conductive material, or multilayers thereof. The metal gate electrode layer 138 may be formed using ALD, PVD, CVD, e-beam evaporation, or another suitable technique. In some embodiments, the work function metal materials may be formed separately for n-channel nanostructure transistors and p-channel nanostructure transistors, which may use different work function materials.

A planarization process such as CMP may be performed on the semiconductor structure 100 to remove the materials of the gate dielectric layer 136 and the gate electrode layer 138 formed above the upper surface of the interlayer dielectric layer 126, in accordance with some embodiments. After the planarization process, the upper surface of the metal gate electrode layer 138 is substantially coplanar with the upper surface of the interlayer dielectric layer 126, in accordance with some embodiments.

The portion of final gate stack 132 wrapping around the nanostructures 108 combines with the neighboring source/drain features 120 to form a nanostructure transistor, such as an n-channel GAA FET device or a p-channel GAA FET device, in accordance with some embodiments. The final gate stack 132 engages the channel region so that current can flow between the source/drain regions during operation.

It is understood that the semiconductor structure 100 may undergo further CMOS processes to form various features over the semiconductor structure 100, such as contact plugs to source/drain features, conductive vias, metal lines, inter metal dielectric layers, passivation layers, etc.

Although FIGS. 2D-1 and 2D-2 only show one transistor of the semiconductor structure 100, the semiconductor structure 100 may include various types of transistors having different threshold voltages (Vt). These transistors may be formed in different device regions such as a logic device region, a memory device region, an analog region, a peripheral region, or a combination thereof, and may be formed with different gate materials, in accordance with some embodiments.

The threshold voltage may depend on the semiconductor material of the FET channel region and/or the effective work function (EWF) value of a gate stack of the FET. For example, for an n-type FET, reducing the difference between the EWF value(s) of the NFET gate stack and the conduction band energy of the material (e.g., 4.1 eV for Si or 3.8 eV for SiGe) of the NFET channel region can reduce the NFET threshold voltage. For a p-type FET, reducing the difference between the EWF value(s) of the PFET gate stack and the valence band energy of the material (e.g., 5.2 eV for Si or 4.8 eV for SiGe) of the PFET channel region can reduce the PFET threshold voltage. The EWF values of the FET gate structures may depend on the thickness and/or material composition of each of the layers of the gate stack. Accordingly, FETs can be manufactured with different threshold voltages by adjusting the thickness and/or material composition of the gate stacks.

As used herein, the term “n-type work function metal (nWFM)” defines a metal or a metal-containing material with a work function that is closer to a conduction band energy than a valence band energy of semiconductor material of a FET channel region. In some embodiments, the term “n-type work function metal (nWFM)” defines a metal or a metal-containing material with a work function of less than 4.5 eV.

As used herein, the term “p-type work function metal (pWFM)” defines a metal or a metal-containing material with a work function that is closer to a valence band energy than a conduction band energy of a semiconductor material of a FET channel region. In some embodiments, the term “p-type work function metal (pWFM)” defines a metal or a metal-containing material with a work function that is equal to or greater than 4.5 eV.

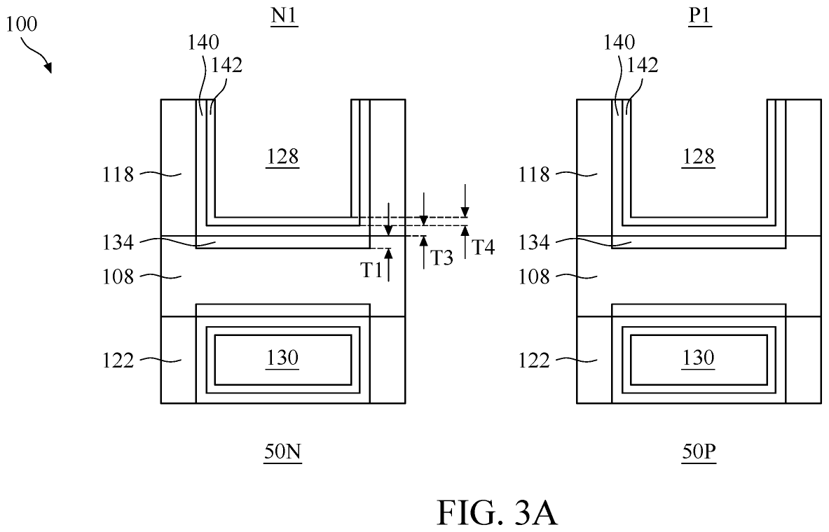

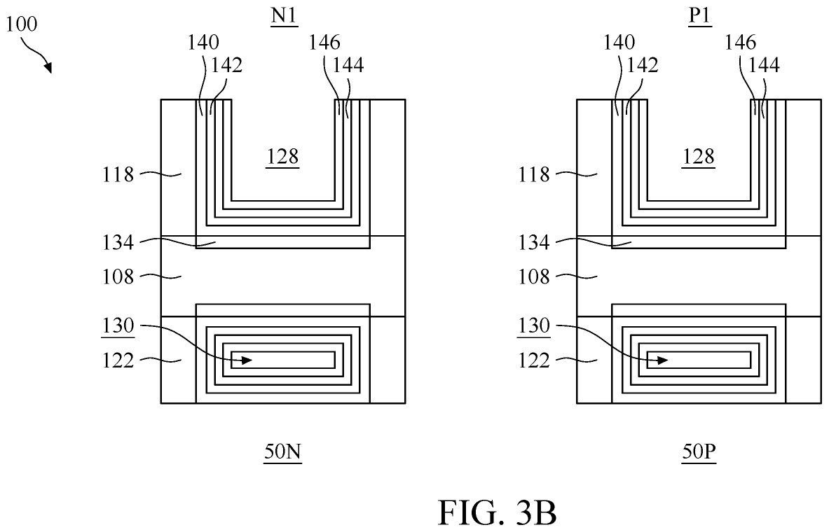

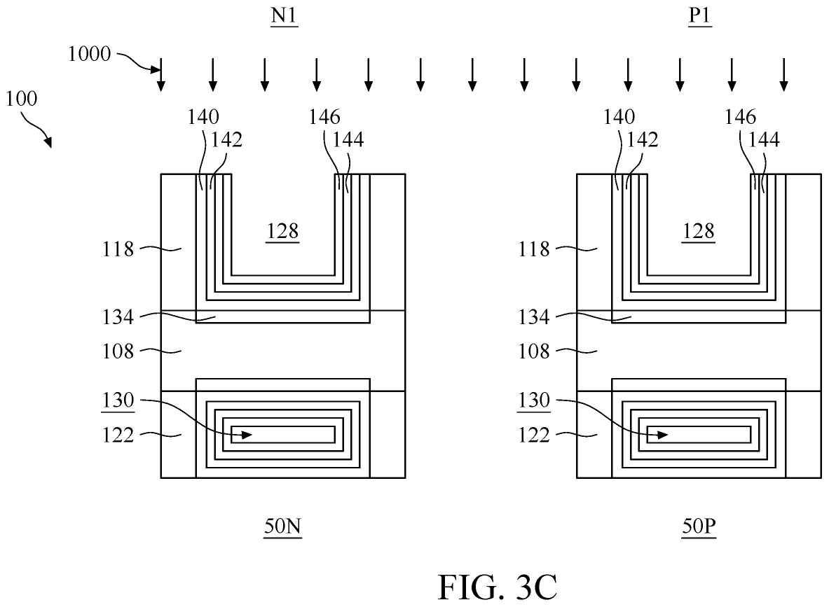

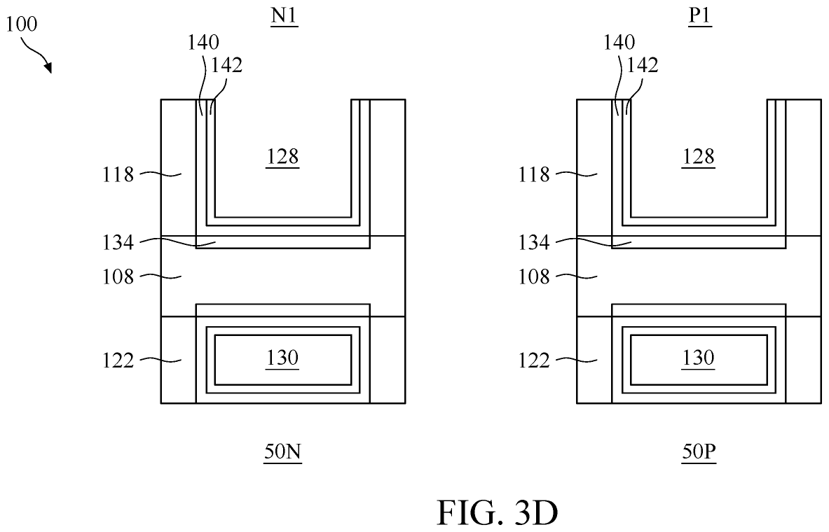

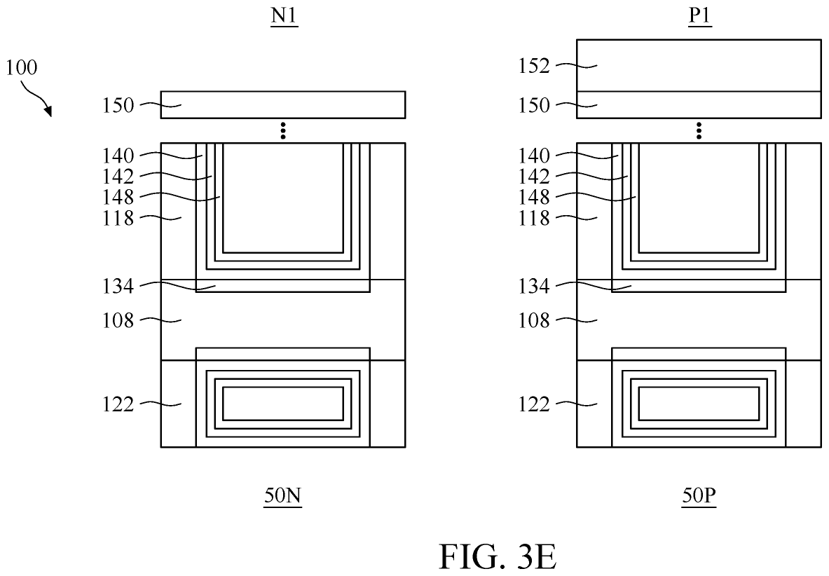

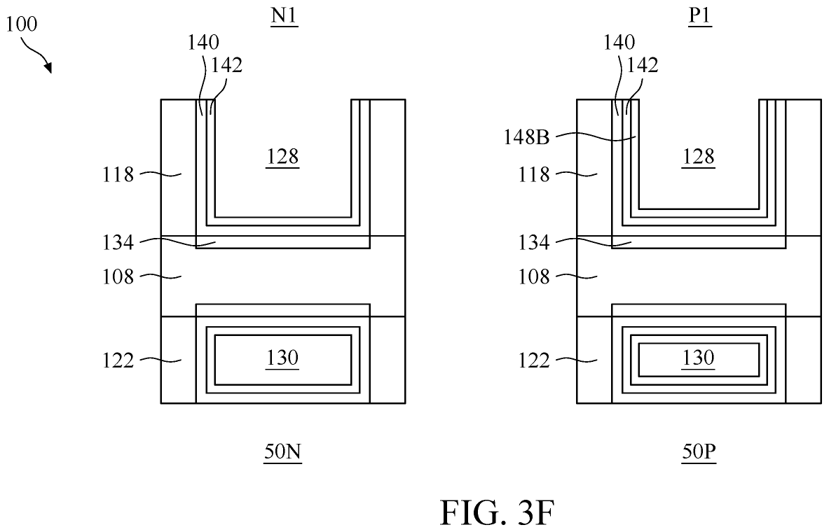

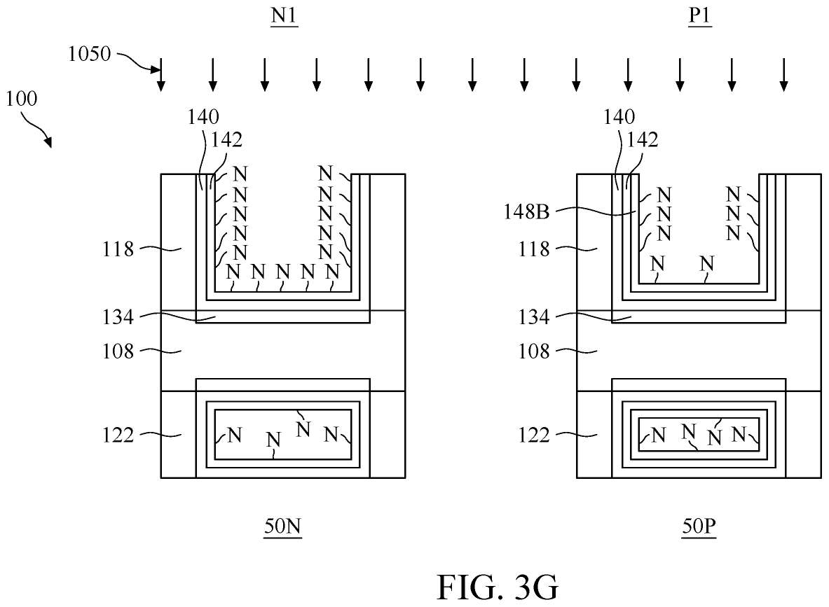

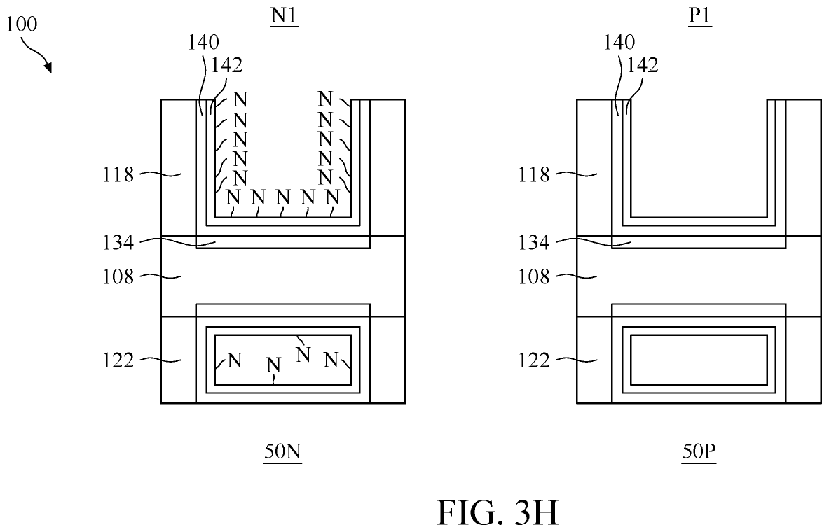

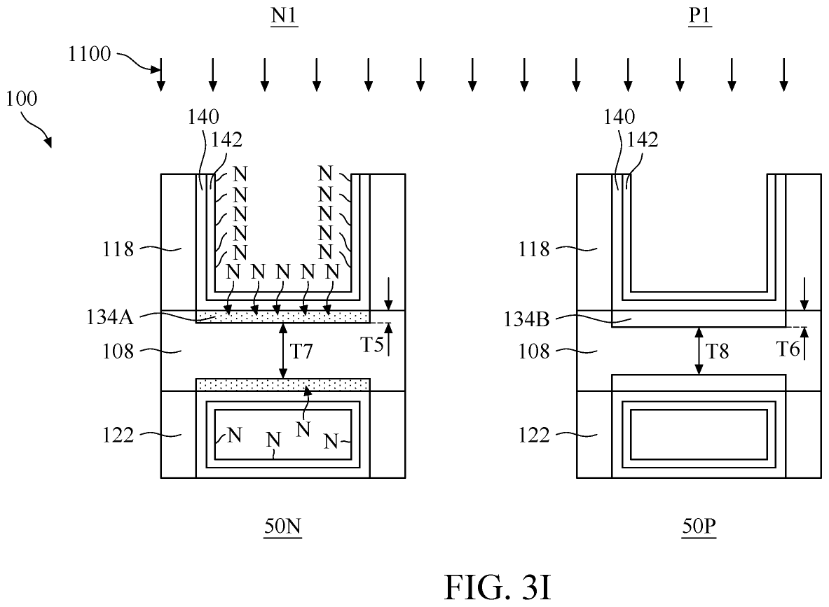

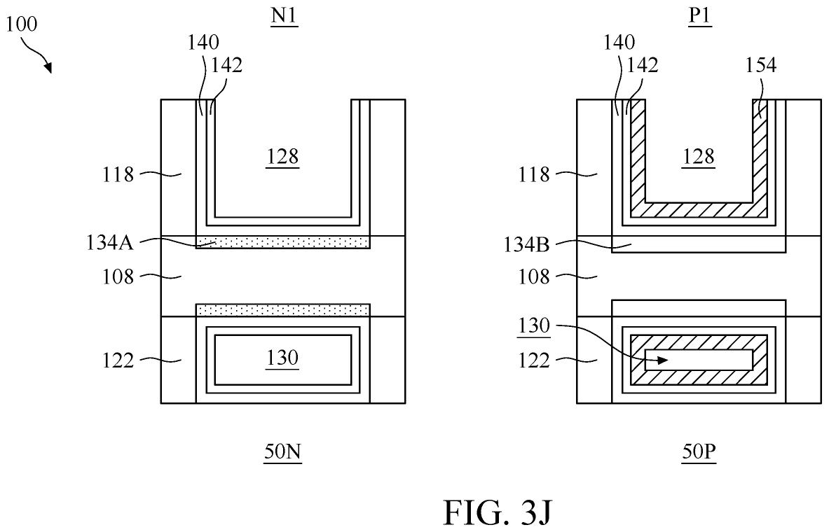

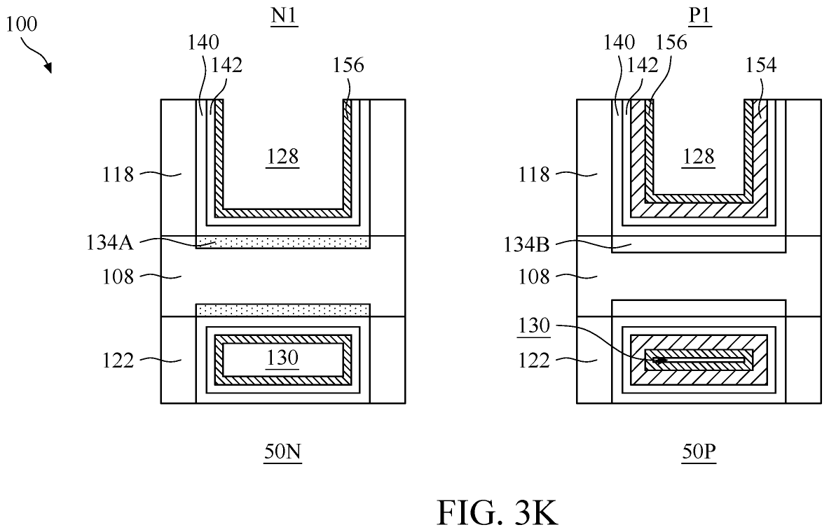

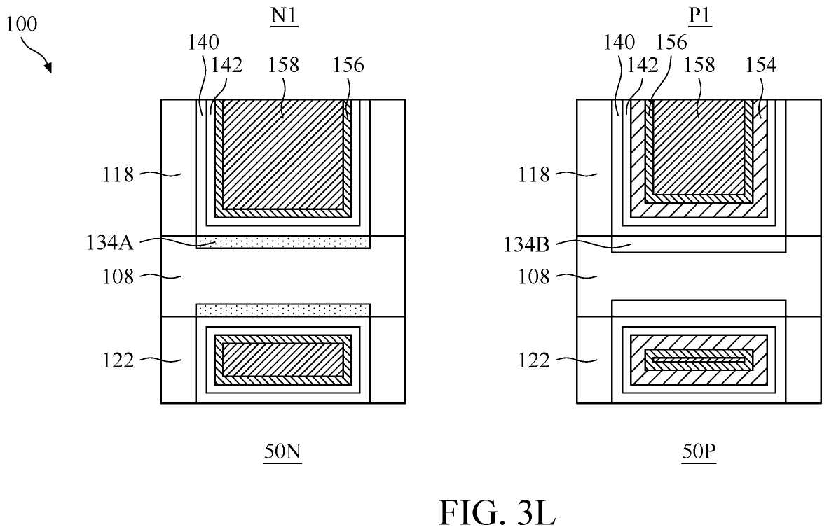

FIGS. 3A through 3L are cross-sectional views illustrating an incorporation of dopants into an interfacial layer and the formation of final gate stacks at various intermediate stages, in accordance with some embodiments of the disclosure. FIGS. 3A through 3L illustrate a portion of a semiconductor structure 100 corresponding to area R of FIG. 2D-1.

FIG. 3A illustrates the semiconductor structure 100 after the formation of an interfacial layer 134, a first high-k dielectric layer 140 and a second high-k dielectric layer 142, in accordance with some embodiments.

The substrate 102 includes device regions 50N and 50P, as shown in FIG. 3A, in accordance with some embodiments. In some embodiments, the device regions 50N and 50P are defined in a logic device region of the substrate 102. In some embodiments, an n-type transistor N1 is predetermined to be formed on the nanostructures 108 in the device region 50N and has a threshold voltage Vn1. Here, 0<Vn1. In some embodiments, a p-type transistor P1 is predetermined to be formed on the nanostructures 108 in the device region 50P and has a threshold voltage Vp1. Here, Vp1<0. In some embodiments, the n-type transistor N1 is an n-channel nanostructure transistor, and the p-type transistor P1 is a p-channel nanostructure transistor. In some embodiments, the n-type transistor N1 and the p-type transistor P1 may be electrically connected to form a logic device.

After the interfacial layer 134 is formed on and around the nanostructures 108, a first high-k dielectric layer 140 and a second high-k dielectric layer 142 are sequentially formed on and around the interfacial layer 134 in the device region 50N and the device region 50P, as shown in FIG. 3A, in accordance with some embodiments. The first high-k dielectric layer 140 and the second high-k dielectric layer 142 collectively serve as the gate dielectric layer 136 shown in FIG. 2D-1, in accordance with some embodiments.

In some embodiments, the first high-k dielectric layer 140 and the second high-k dielectric layer 142 may be, or include, hafnium oxide (HfO₂), TiO₂, HfZrO, Ta₂O₃, HfSiO₄, ZrO₂, ZrSiO₂, LaO, Al₂O₃, ZrO, TiO, Ta₂O₅, Y₂O₃, SrTiO₃ (STO), BaTiO₃ (BTO), BaZrO, HfZrO, HfLaO, HfSiO, LaSiO, AlSiO, HfTaO, HfTiO, or (Ba,Sr)TiO₃ (BST). In some embodiments, the dielectric constant of the second high-k dielectric layer 142 is greater than the dielectric constant of the first high-k dielectric layer 140. In an embodiment, the first high-k dielectric layer 140 is a hafnium oxide layer, and the second high-k dielectric layer 142 is a zirconium oxide layer.

In some embodiments, the first high-k dielectric layer 140 and the second high-k dielectric layer 142 are deposited using ALD, PVD, CVD, and/or another suitable technique. In some embodiments, the first high-k dielectric layer 140 has a thickness T3 in a range from 5 Å to about 20 Å. In some embodiments, the second high-k dielectric layer 142 has a thickness T4 in a range from 5 Å to about 20 Å. In some embodiments, the thickness T4 of second high-k dielectric layer 142 may be greater than, equal to or less than, the thickness T3 of the first high-k dielectric layer 140.

In some embodiments, before depositing the second high-k dielectric layer 142, a dipole material (not shown) may be deposited on the first high-k dielectric layer 140 followed by a patterning process (e.g., including photolithography and etching processes). An anneal process is performed to drive the electric dipoles (e.g., n-type dipole and/or p-type dipole) from the dipole material into the first high-k dielectric layer 140, and then the dipole material is removed using an etching process.

For example, n-type dipole materials may be lanthanum oxide (La₂O₃), yttrium oxide (Y₂O₃), titanium oxide (TiO₂), or another suitable material. P-type dipole materials may be germanium oxide, aluminum oxide, gallium oxide, or zinc oxide, or another suitable material. The n-dipole materials serve to reduce the threshold voltage of n-type devices and/or increase the absolute value of the threshold voltage of p-type devices. The p-dipole material serves to reduce the absolute value of the threshold voltage of p-type devices and/or increase the threshold voltage of n-type devices. The concentration of the electric dipoles in the high-k dielectric layer 140 may be positively correlated with the thickness of the as-deposited dipole material.

As a result, for a semiconductor structure having various devices with different threshold voltages (e.g., extremely low voltage, ultra-low voltage, ultra-low voltage along with low leakage, low voltage along with low leakage, or standard voltage), by performing multiple sets of depositions of dipole material, patterning process and anneal process, it can be realized that the first high-k dielectric layers 140 of various devices have the electric dipoles with different concentrations, so various devices can have different threshold voltages.

FIG. 3B illustrates the semiconductor structure 100 after the formation of a first capping layer 144 and a second capping layer 146, in accordance with some embodiments.

A first capping layer 144 and a second capping layer 146 are sequentially formed on and around the second high-k dielectric layer 142 in the device region 50N and the device region 50P, as shown in FIG. 3B, in accordance with some embodiments. In some embodiments, the first capping layer 144 is made of titanium nitride and/or titanium nitride doped with silicon (TSN), which is deposited using ALD or CVD, in accordance with some embodiments. In some embodiments, the second capping layer 146 is made of silicon, which is deposited using ALD or CVD, in accordance with some embodiments.

FIG. 3C illustrates the semiconductor structure 100 after an anneal process 1000, in accordance with some embodiments.

Afterward, an anneal process 1000 is performed on the semiconductor structure 100, in accordance with some embodiments. In some embodiments, the anneal process 1000 includes a post cap anneal (PCA) process. In some embodiments, the PCA process is a spike anneal, furnace anneal, or flash anneal, which is performed in an ambient containing N₂. For example, the temperature may be in a range from about 900° C. to about 950° C. The PCA process may facilitate boosting the p-type dipoles in the first high-k dielectric layer 140 for the p-type transistor P1. In some embodiments, the anneal process 1000 may optionally include a defect recovery anneal (DRA) process. In some embodiments, the DRA process is a spike anneal, furnace anneal, or flash anneal, which is performed in an ambient containing N₂ and at a temperature in a range from about 500° C. to about 1000° C. The DRA process may facilitate repairing defects in the source/drain features 120, and/or reactivating the dopants in the source/drain features 120.

FIG. 3D illustrates the semiconductor structure 100 after the removal of the first capping layer 144 and the second capping layer 146, in accordance with some embodiments.

The first capping layer 144 and the second capping layer 146 are removed using one or more etching processes until the second high-k dielectric layer 142 is exposed, as shown in FIG. 3D, in accordance with some embodiments. The etching processes may be an anisotropic etching process such as dry plasma etching, an isotropic etching process such as dry chemical etching, remote plasma etching, wet chemical etching, or a combination thereof. Afterward, a post deposition anneal (PDA) process may be optionally performed on the semiconductor structure 100, in accordance with some embodiments. In some embodiments, the PDA process is a spike anneal, which is performed at a temperature of about 850° C. to about 950° C., and in an ambient containing NH₃.

FIG. 3E illustrates the semiconductor structure 100 after formation of a hard mask layer 148, a fill layer 150 and a patterned photoresist layer 152, in accordance with some embodiments.

A hard mask layer 148 is formed on and around the second high-k dielectric layer 142 in the device region 50N and the device region 50P, as shown in FIG. 3E, in accordance with some embodiments. The hard mask layer 148 partially fills the gate trenches 128 and the gaps 130, in accordance with some embodiments. In some embodiments, the hard mask layer 148 is made of a metal oxide dielectric such as Al₂O₃, LaO, HfO₂, Ta₂O₅, TiO₂, ZrO₂, Y₂O₃, or a combination thereof. In an embodiment, the hard mask layer 148 is an AlO layer. In some embodiments, the hard mask layer 148 is globally and conformally deposited using ALD, CVD (such as LPCVD, PECVD, HDP-CVD, HARP, and FCVD), physical vapor deposition (PVD), another suitable method, or a combination thereof.

A fill layer 150 is formed over the hard mask layer 148 and overfills the remainders of the gate trenches 128 and the gaps 130, as shown in FIG. 3E, in accordance with some embodiments. The fill layer 150 may be used as a planarization layer to provide a substantially planar surface for a following photolithography process. In some embodiments, the fill layer 150 is a bottom anti-reflective coating (BARC) layer such as an inorganic material or an organic material (e.g., polymer, oligomer, or monomer). In some embodiments, the fill layer 150 is made of organic material including carbon and oxygen, which is made of cross-linked photo-sensitive material. In some embodiments, the fill layer 150 is formed by spin-on coating process, a CVD process (such as LPCVD, PECVD, HDP-CVD, HARP or FCVD), another suitable method, or a combination thereof.

A patterned photoresist layer 152 is formed over the fill layer 150, as shown in FIG. 3E, in accordance with some embodiments. The patterned photoresist layer 152 covers the device region 50P and exposes the device region 50N, in accordance with some embodiments. The patterned photoresist layer 152 is formed by a photolithography process, in accordance with some embodiments.

The photolithography process can include forming a photoresist material over the fill layer 150 (for example, by spin coating), performing a pre-exposure baking process, performing an exposure process using a mask (or a reticle), performing a post-exposure baking process, and performing a developing process. During the exposure process, the photoresist layer is exposed to radiation energy (such as ultraviolet (UV) light, deep UV (DUV) light, or extreme UV (EUV) light), where the mask blocks, transmits, and/or reflects radiation to the photoresist layer depending on a mask pattern of the mask and/or mask type, so that an image is projected onto the photoresist layer that corresponds with the mask pattern. Since the photoresist layer is sensitive to radiation energy, exposed portions of the resist layer chemically change, and exposed (or non-exposed) portions of the photoresist material are dissolved during the developing process depending on characteristics of the resist layer and characteristics of a developing solution used in the developing process. After development, the patterned photoresist material forms the patterned photoresist layer 152, which includes a resist pattern that corresponds with the mask.

FIG. 3F illustrates the semiconductor structure 100 after an etching process, in accordance with some embodiments.

An etching process is performed using the patterned photoresist layer 152 to remove portions of the fill layer 150 and the hard mask layer 148 from the device region 50N, thereby exposing the second high-k dielectric layer 142 in the device region 50N, as shown in FIG. 3F, in accordance with some embodiments. In some embodiments, the etching process may be an anisotropic etching process such as dry plasma etching, an isotropic etching process such as dry chemical etching, remote plasma etching, wet chemical etching, or a combination thereof.

The remaining portion of the hard mask layer 148 is referred to as a patterned hard mask layer 148B, which covers the device region 50P, in accordance with some embodiments. The portions of the patterned photoresist layer 152 and the fill layer 150 in the device region 50P may be removed in the etching process or by an additional process (e.g., an etching process or an ashing process), thereby exposing the patterned hard mask layer 148B, in accordance with some embodiments.

FIG. 3G illustrates the semiconductor structure 100 after a plasma treatment 1050, in accordance with some embodiments.

A plasma treatment 1050 is performed on the semiconductor structure 100, as shown in FIG. 3G, in accordance with some embodiments. In some embodiments, the plasma treatment 1050 is used to provide sufficient dopants (e.g., nitrogen radicals) onto the exposed surface of the semiconductor structure 100. In some embodiments, the plasma treatment 1050 includes a decoupled plasma nitridation (DPN) process.

The semiconductor structure 100 is placed in a plasma treatment chamber, in accordance with some embodiments. During the plasma treatment 1050, the plasma treatment chamber provides a bias voltage in a range from about 10 volts (V) to about 900 V, and an RF source power in a range from 100 watts (W) to about 3000 W, in accordance with some embodiments. During the plasma treatment 1050, a nitrogen-containing gas (e.g., N₂, NH₃, or a combination thereof) is directed into the plasma treatment chamber with a flow rate in a range from about 50 standard cubic centimeters per minute (sccm) to about 1000 sccm along with a carrier gas (e.g., Ar) with a flow rate in a range from about 50 sccm to about 10000 sccm, in accordance with some embodiments. In some embodiments, the plasma treatment 1050 is performed at a temperature of about 450° C. to about 700° C. (e.g., in a range from about 550° C. to about 600° C.) for a time period of about 10 microseconds to about 1000 microseconds.

The carrier gas (e.g., Ar) is ignited to form a plasma in the plasma treatment chamber, and the nitrogen-containing gas is activated by the plasma to form nitrogen radicals, in accordance with some embodiments. The nitrogen radicals are introduced onto and adsorbed onto the exposed surface of the second high-k dielectric layer 142 in the device region 50N, in accordance with some embodiments. In some embodiments, the nitrogen radicals are also adsorbed onto the exposed surface of the patterned hard mask layer 148B in the device region 50P, in accordance with some embodiments.

FIG. 3H illustrates the semiconductor structure 100 after an etching process, in accordance with some embodiments.

An etching process is performed to remove the patterned hard mask layer 148B from the device region 50P, thereby exposing the second high-k dielectric layer 142 in the device region 50P, as shown in FIG. 3H, in accordance with some embodiments. In some embodiments, the etching process may be an anisotropic etching process such as dry plasma etching, an isotropic etching process such as dry chemical etching, remote plasma etching, wet chemical etching, or a combination thereof.

After the etching process, the nitrogen radicals substantially remain adsorbed on the surface of the second high-k dielectric layer 142 in the device region 50N, in accordance with some embodiments. The exposed surface of the second high-k dielectric layer 142 in the device region 50P is fresh, and no nitrogen radicals are adsorbed on the second high-k dielectric layer 142 in the device region 50P, in accordance with some embodiments.

FIG. 3I illustrates the semiconductor structure 100 after an anneal process 1100, in accordance with some embodiments.

A anneal process 1100 is performed on the semiconductor structure 100, as shown in FIG. 3I, in accordance with some embodiments. In some embodiments, the anneal process 1100 drives the nitrogen radicals from the surface of the second high-k dielectric layer 142, through the high-k dielectric layers 142 and 140 and into the interfacial layer 134. In some embodiments, the anneal process 1100 includes a post nitridation annealing (PNA), which is a rapid thermal anneal (RTA) process, spike anneal, and/or a combination thereof.

The anneal process 1100 is performed at a temperature of about 700° C. to about 1000° C. (e.g., in a range from about 800° C. to about 900° C.) for a time period of about 5 seconds to about 1000 seconds, and in an ambient containing nitrogen (e.g., N₂, NH₃, or a combination thereof), in accordance with some embodiments. In some embodiments, the temperature of the anneal process 1100 is higher than the temperature of the plasma treatment 1050, and the time period of the anneal process 1100 is longer than the time period of the plasma treatment 1050.

The interfacial layer 134 in the device region 50N is doped or incorporated with nitrogen to form a nitrogen-doped interfacial layer 134A, as shown in FIG. 3I, in accordance with some embodiments. In some embodiments, the nitrogen-doped interfacial layer 134A is nitrogen-doped silicon oxide and has a dielectric constant of greater than about 3.9, or greater than about 4.3.

For the n-type transistor N1, the incorporation of nitrogen into the interfacial layer 134 can reduce its capacitance equivalent thickness, for example, by about 1.8 Å to about 2.2 Å, in accordance with some embodiments. In some embodiments, the capacitance equivalent thickness of the n-type transistor N1 with the nitrogen-doped interfacial layer 134A is in a range from about 12.2 Å to about 12.6 Å.

In the anneal process 1100, due to the incorporation of nitrogen, the interfacial layer 134 in the device region 50N substantially does not regrow, or only slightly regrows, in accordance with some embodiments. In some embodiments, the nitrogen-doped interfacial layer 134A has a thickness T5 that is substantially equal to or slightly greater than the thickness T1 and in a range from 5 Å to about 15 Å.

In the anneal process 1100, the interfacial layer 134 in the device region 50P regrows to form a thickened interfacial layer 134B, in accordance with some embodiments. In some embodiments, the thickened interfacial layer 134B has a thickness T6 that is greater than the thickness T1 (and the thickness T5) and in a range from 5.5 Å to about 16.5 Å.

The regrowth of the interfacial layer 134 in the device region 50P may consume the semiconductor material of the nanostructures 108 in the device region 50P, in accordance with some embodiments. As such, the thickness T7 of the nanostructures 108 in the device region 50N is greater than the thickness T8 of the nanostructures 108 in the device region 50P, in accordance with some embodiments. In some embodiments, the thickened interfacial layer 134B is non-doped, and thus has a lower dielectric constant than the dielectric constant of the nitrogen-doped interfacial layer 134A, e.g., being approximately 3.9.

For the p-type transistor P1, the increase in thickness of the interfacial layer 134 in the device region 50P can increase the capacitance equivalent thickness of the p-type transistor P1, for example, by about 0.5 Å to about 0.9 Å. In some embodiments, the capacitance equivalent thickness of the p-type transistor P1 with the thickened interfacial layer 134B is in a range from about 13.4 Å to about 13.8 Å.

The capacitance equivalent thickness of the p-type transistor P1 is thicker than the capacitance equivalent thickness of the n-type transistor N1, for example, by about 0.8 Å to about 1.4 Å, in accordance with some embodiments. In some embodiments, the ration of the capacitance equivalent thickness of the p-type transistor P1 to the capacitance equivalent thickness of the n-type transistor N1 is in a range from about 0.88 to about 0.94.

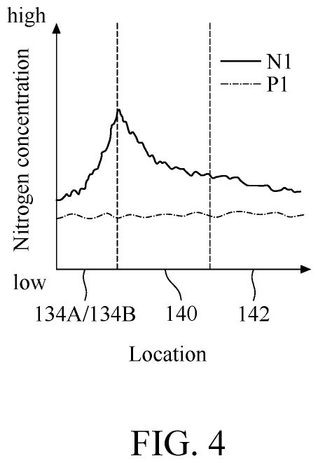

FIG. 4 is a schematic view exhibiting that distributions of the nitrogen concentrations vary with location, in accordance with some embodiments of the disclosure.

The average nitrogen concentration of the nitrogen-doped interfacial layer 134A of the n-type transistor N1 is greater than the average nitrogen concentration of the thickened interfacial layer 134B of the p-type transistor P1, as shown in FIG. 4, in accordance with some embodiments. Because the nitrogen atoms tend to accumulate on the interface between the interfacial layer 134A and the first high-k dielectric layer 140, the maximum nitrogen concentration occurs at the interface between the nitrogen-doped interfacial layer 134A and the first high-k dielectric layer 140, in accordance with some embodiments.

In addition, the average nitrogen concentration of the high-k dielectric layers 140 and 142 of the n-type transistor N1 is greater than the average nitrogen concentration of the high-k dielectric layers 140 and 142 of the p-type transistor P1, in accordance with some embodiments. In some embodiments, the nitrogen concentration increases from the interior of the interfacial layer 134A to the interface between the interfacial layer 134A and the first high-k dielectric layer 140. In some embodiments, the nitrogen concentration decreases from the interface between the interfacial layer 134A and the first high-k dielectric layer 140 to the interior of the first high-k dielectric layer 140.

FIG. 3J illustrates the semiconductor structure 100 after the formation of a p-type work function layer 154, in accordance with some embodiments.

A p-type work function layer 154 is formed on and around the second high-k dielectric layer 142 in the device region 50P, as shown in FIG. 3J, in accordance with some embodiments. At the device region 50P, the p-type work function layer 154 partially fills the gate trench 128 and the gaps 130, in accordance with some embodiments.

In some embodiments, the p-type work function layer 154 is p-type work function metal, e.g., TiN, WN, WCN, TaN, Ru, Co, W, another suitable p-type work function metal, or a combination thereof. The material of the p-type work function layer 154 is selected to assist in providing a desired work function for the p-type transistor P1. In some embodiments, the metal for the p-type work function layer 154 is deposited over the semiconductor structure 100 using ALD, CVD, PVD, another suitable technique, or a combination thereof. In some embodiments, a patterning process is then performed to remove metal for the p-type work function layer 154 from the device region 50N. In some embodiments, the patterning process includes photolithography and etching processes. In some embodiments, the p-type work function layer 154 has a thickness in a range from about 10.0 Å to about 30.0 Å.

FIG. 3K illustrates the semiconductor structure 100 after the formation of an n-type work function layer 156, in accordance with some embodiments.

An n-type work function layer 156 is formed over the semiconductor structure 100, as shown in FIG. 3K, in accordance with some embodiments. The n-type work function layer 156 is formed on the second high-k dielectric layer 142 in the device region 50N and on the p-type work function layer 154 in the device region 50P, in accordance with some embodiments. The n-type work function layer 156 partially fills the gate trenches 128 and the gaps 130, in accordance with some embodiments.

In some embodiments, the n-type work function layer 156 is n-type work function metal, e.g., Ti, Ag, Al, TiAl, TiAlN, TiAlC, TaAl, TaC, TaCN, TaSiN, TaAlC, Mn, Zr, another suitable n-type work function metal, or a combination thereof. The material of the n-type work function layer 156 is selected to assist in providing a desired work function for the n-type transistor N1. The n-type work function layer 156 is deposited using ALD, CVD, PVD, another suitable technique, or a combination thereof. In some embodiments, the n-type work function layer 156 has a thickness in a range from about 5.0 Å to about 30.0 Å.

Compared with the case where the interface layer is not doped with nitrogen, the thickness of the n-type work function layer 156 can be thinned down to maintain the threshold voltage of the n-type transistor N1 at a desired value, because the interfacial layer 134 doped with nitrogen lower the threshold voltage for an n-type device (e.g., the n-type transistor N1), in accordance with some embodiments. In some embodiments, the n-type work function layer 156 is thinner than the p-type work function layer 154.

One approach to manufacturing the p-type device with an extremely low or ultra-low threshold voltage is that the channel for the p-type device uses a different material than the channel for the n-type device, for example, silicon channel for an n-type device and silicon germanium channel for a p-type device. However, the material difference between the n-type and p-type active regions may increase the difficulty of manufacturing processes for the semiconductor device.

In accordance with the embodiments of the present disclosure, the n-type work function layer 156 formed in the device region 50P is also thinned down, thereby lowering the absolute value of the threshold voltage of the p-type transistor P1 (i.e., approaching zero). Therefore, this may be beneficial to realize that the p-type transistor P1 uses the silicon channel instead of the silicon germanium channel.

FIG. 3L illustrates the semiconductor structure 100 after the formation of a gate metal fill layer 158, in accordance with some embodiments.

A gate metal fill layer 158 is formed on the n-type work function layer 156 in the device regions 50N and 50P to overfill the remainders of the gate trenches 128 and the gaps 130, as shown in FIG. 3L, in accordance with some embodiments. In some embodiments, the gate metal fill layer 158 is made of metal material with lower resistance, for example, tungsten (W), titanium (Ti), silver (Ag), ruthenium (Ru), molybdenum (Mo), copper (Cu), cobalt (Co), Al, iridium (Ir), nickel (Ni), metal alloys, and a combination thereof. In some embodiments, the gate metal fill layer 158 is formed using ALD, CVD, PVD, electroplating process, another suitable technique, or a combination thereof. In some embodiments, the gate metal fill layer 158 has a thickness in a range from about 10 Å to about 1000 Å.

In some embodiments, the n-type work function layer 156 and the gate metal fill layer 158 combine to form the metal gate electrode layer (e.g., the metal gate electrode layer 138 shown in FIG. 2D-1) of the n-type transistor N1. In some embodiments, the p-type work function layer 154, the n-type work function layer 156 and the gate metal fill layer 158 combine to form the metal gate electrode layer (e.g., the metal gate electrode layer 138 shown in FIG. 2D-1) of the p-type transistor P1.

In accordance with the embodiments of the present disclosure, for an n-type device (e.g., the n-type transistor N1), the thinner capacitance equivalent thickness may enhance the gate control capability over the channel, thereby increasing the speed of the resulting semiconductor device, which may gain DC performance (the percentage proportion of the on-state current to off-state current ratio to a target value) and RO performance (the percentage proportion of the speed to standby power ratio to a target value) of the resulting semiconductor device. If the capacitance equivalent thickness of the n-type transistor N1 is too thick, the gate control capability may be not sufficiently improved. If the capacitance equivalent thickness of the n-type transistor N1 is too thin, the off-state gate leakage may increase.

In addition, in accordance with the embodiments of the present disclosure, for an n-type device (e.g., the n-type transistor N1), the reduction in the threshold voltage caused by the reduction of the capacitance equivalent thickness can be compensated by reducing the thickness of the work function layer (e.g., the n-type work function layer 156). Global thinning down of the n-type work function layer may be beneficial to obtain a p-type device with an extremely low or ultra-low threshold voltage.

Furthermore, because the interfacial layer 134 of the p-type transistor P1 is not doped with nitrogen, the capacitance equivalent thickness of the p-type transistor P1 does not reduce, but increases due to the thickness of the interfacial layer 134 increases. The reduction in capacitance equivalent thickness of the p-type transistor may lead to an increase in the absolute value of the threshold voltage of the p-type transistor P1. As a result, it is not conducive to obtain a p-type device with an extremely low or ultra-low threshold voltage.

In addition, the incorporation of nitrogen into the high-k dielectric layer 140 and 142 of the n-type transistor N1 can reduce the diffusion of metal (e.g., Al) from the n-type work function layer 156 at the boundary between the n-type device region (e.g., 50N) and the p-type device region (e.g., 50P). This may reduce the variation of the threshold voltage of the p-type devices.

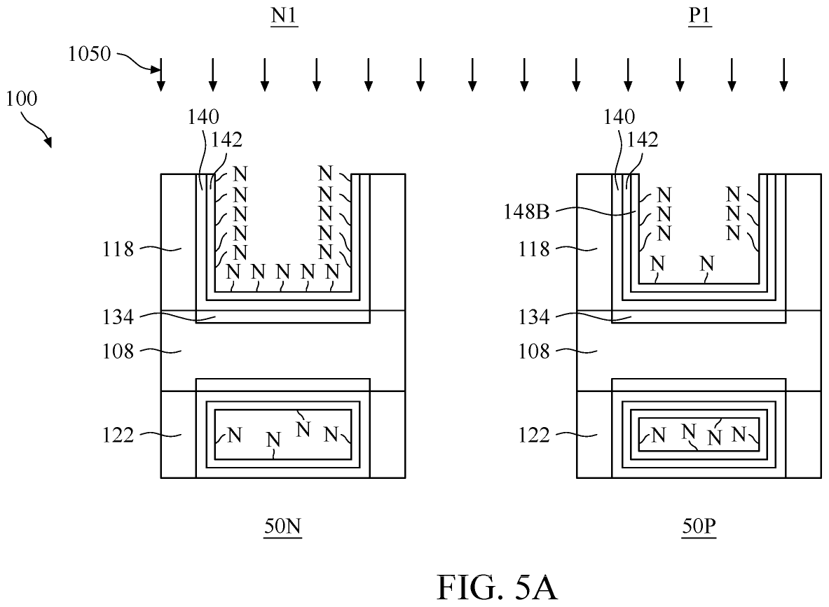

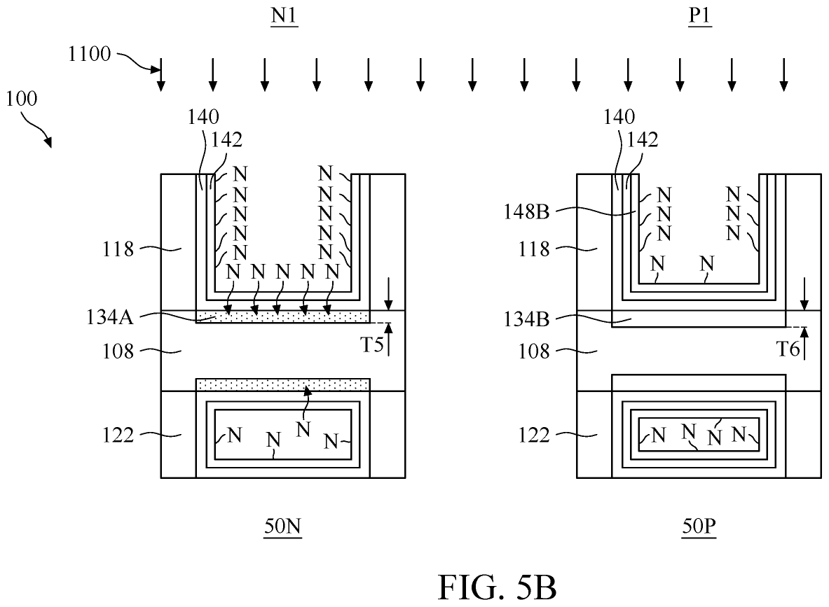

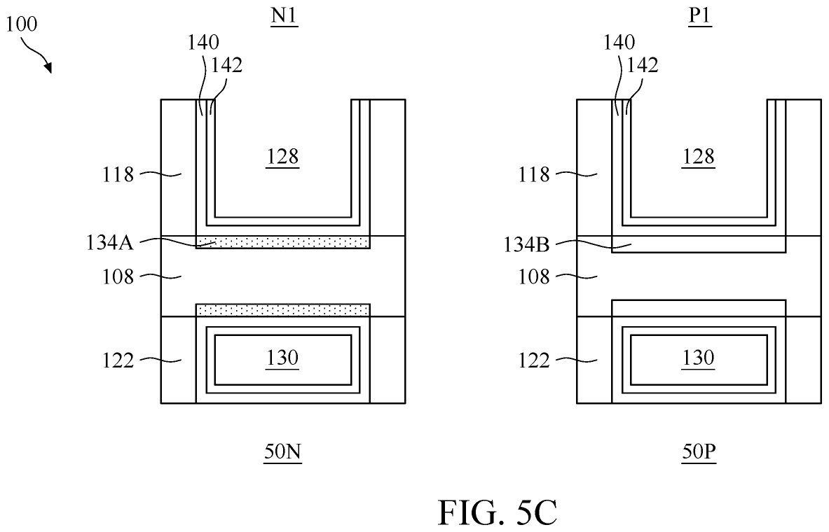

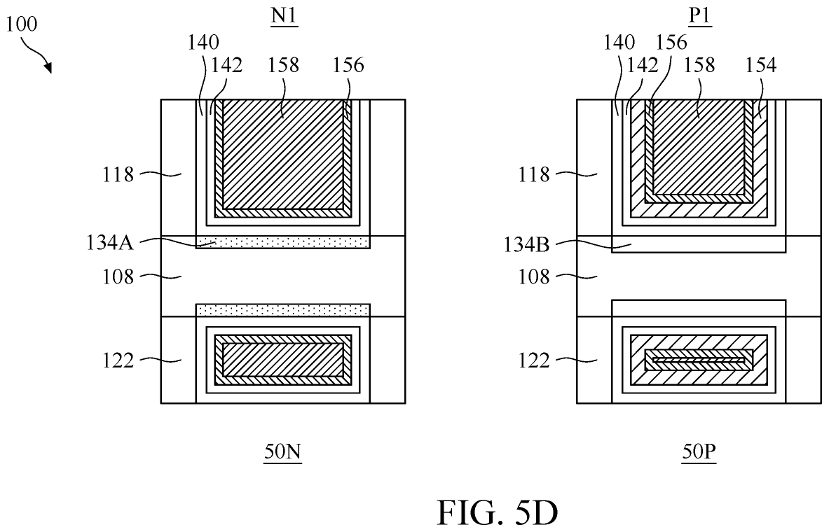

FIGS. 5A through 5D are cross-sectional views illustrating an incorporation of dopants into an interfacial layer and the formation of final gate stacks at various intermediate stages, in accordance with some embodiments of the disclosure. FIGS. 5A through 5D illustrate a portion of a semiconductor structure 100 corresponding to area R of FIG. 2D-1. The embodiments of FIGS. 5A through 5D are similar to the embodiments of FIGS. 3A through 3L except that the patterned mask layer 148B is removed after the incorporation of dopants into an interfacial layer.

FIG. 5A illustrates the semiconductor structure 100 after the plasma treatment 1050, in accordance with some embodiments.

Continuing from FIG. 3G, the plasma treatment 1050 is performed on the semiconductor structure 100, in accordance with some embodiments. The nitrogen radicals are introduced onto and adsorbed onto the exposed surface of the second high-k dielectric layer 142 in the device region 50N and the exposed surface of the patterned hard mask layer 148B in the device region 50P, in accordance with some embodiments.

FIG. 5B illustrates the semiconductor structure 100 after the anneal process 1100, in accordance with some embodiments.

Once the plasma treatment 1050 is performed, the anneal process 1100 is then performed on the semiconductor structure 100, as shown in FIG. 5B, in accordance with some embodiments. In some embodiments, the anneal process 1100 drives the nitrogen radicals from the surface of the second high-k dielectric layer 142 into the interfacial layer 134 in the device region 50N. In some embodiments, the patterned hard mask layer 148B may block the nitrogen radicals from diffusing into the interfacial layer 134 in the device region 50P.

The interfacial layer 134 in the device region 50N is doped with nitrogen to form the nitrogen-doped interfacial layer 134A, and the interfacial layer 134 in the device region 50P regrows to form the thickened interfacial layer 134B, as shown in FIG. 5B, in accordance with some embodiments.

In an embodiment the patterned hard mask layer 148B is made of AlO, the patterned hard mask layer 148B may provide p-type dipoles to the high-k dielectric layers 142 and 140, thereby lowering the absolute value of the threshold voltage of the p-type transistor P1 (i.e., approaching zero). Therefore, this may be beneficial to realize that the p-type transistor P1 uses the silicon channel instead of the silicon germanium channel.

FIG. 5C illustrates the semiconductor structure 100 after an etching process, in accordance with some embodiments.

An etching process is performed to remove the patterned hard mask layer 148B from the device region 50P, thereby exposing the second high-k dielectric layer 142 in the device region 50P, as shown in FIG. 5C, in accordance with some embodiments.

FIG. 5D illustrates the semiconductor structure 100 after the formation of the p-type work function layer 154, the n-type work function layer 156 and the gate metal fill layer 158, in accordance with some embodiments.

The steps discussed above in FIGS. 3J to 3L are performed, thereby forming the p-type work function layer 154, the n-type work function layer 156 and the gate metal fill layer 158, as shown in FIG. 5D, in accordance with some embodiments.

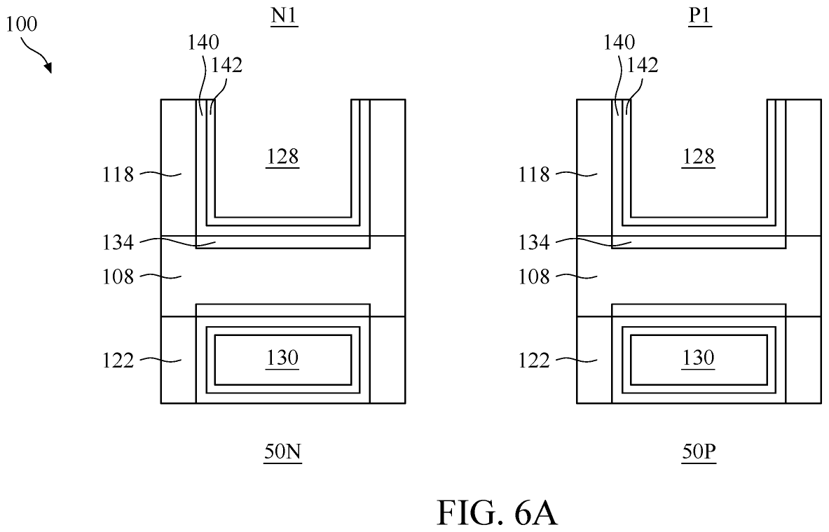

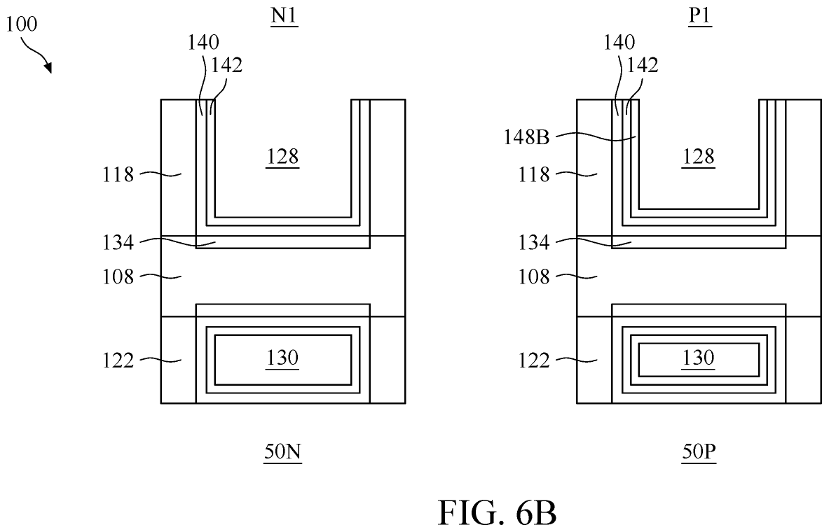

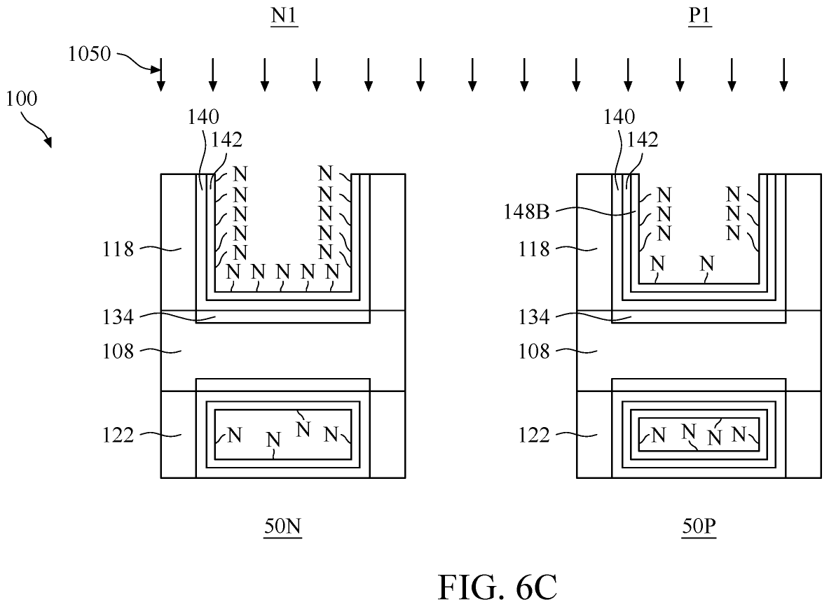

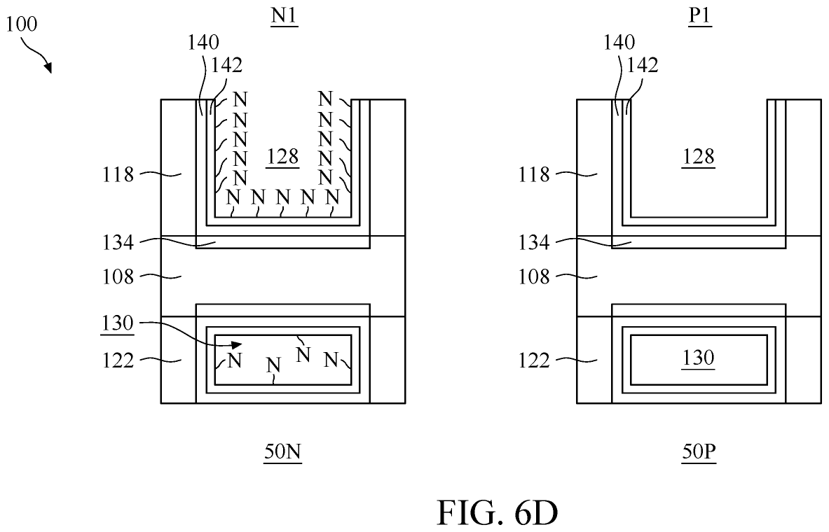

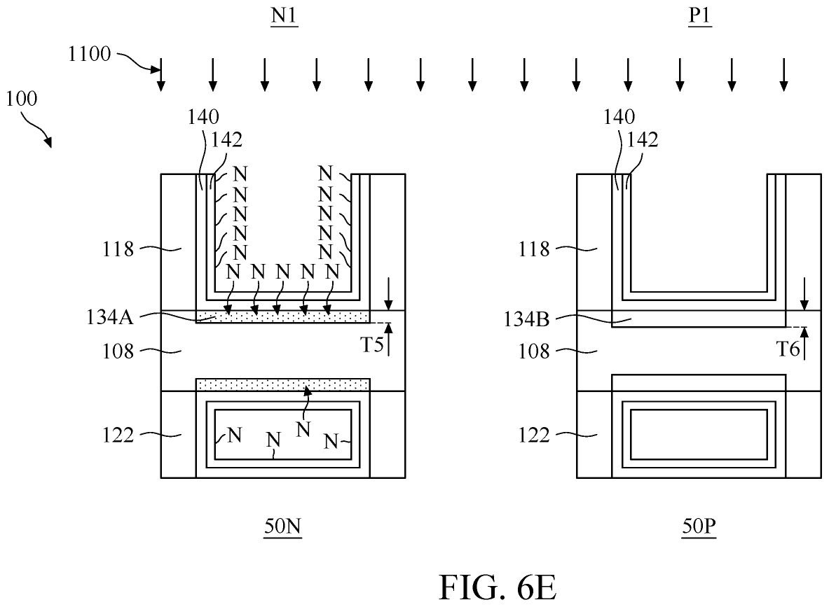

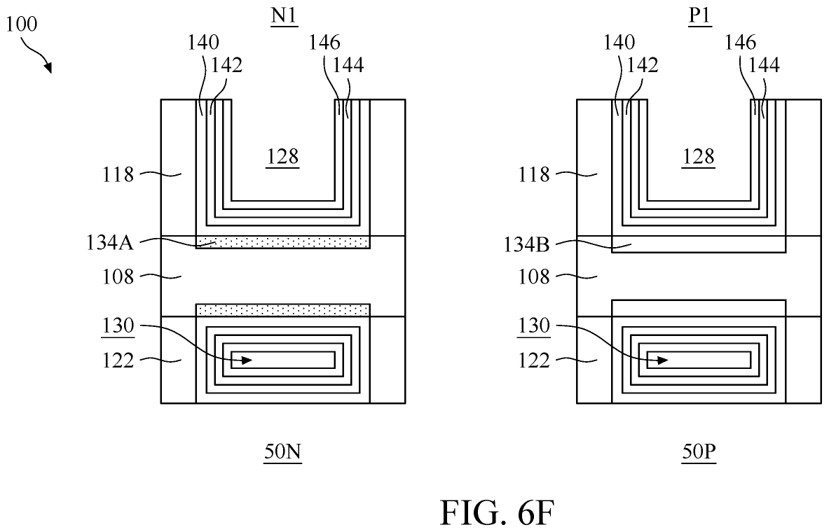

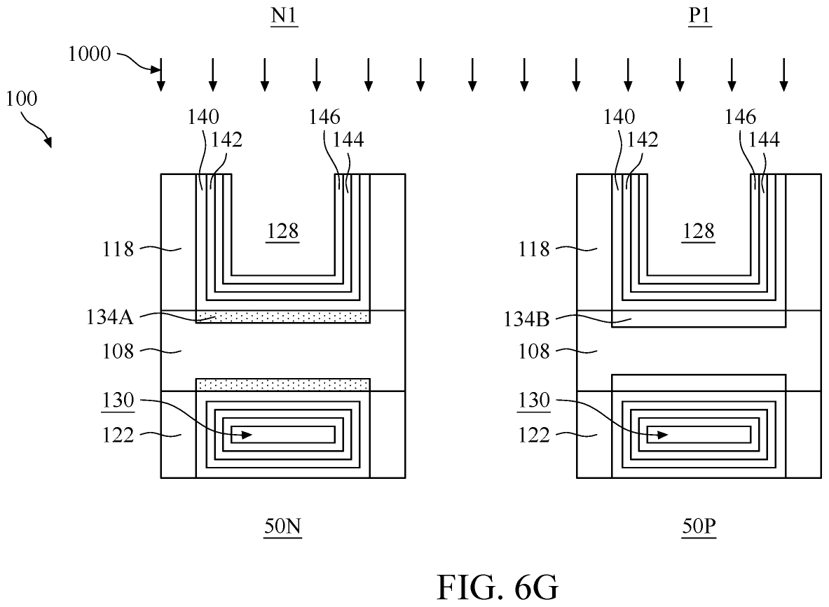

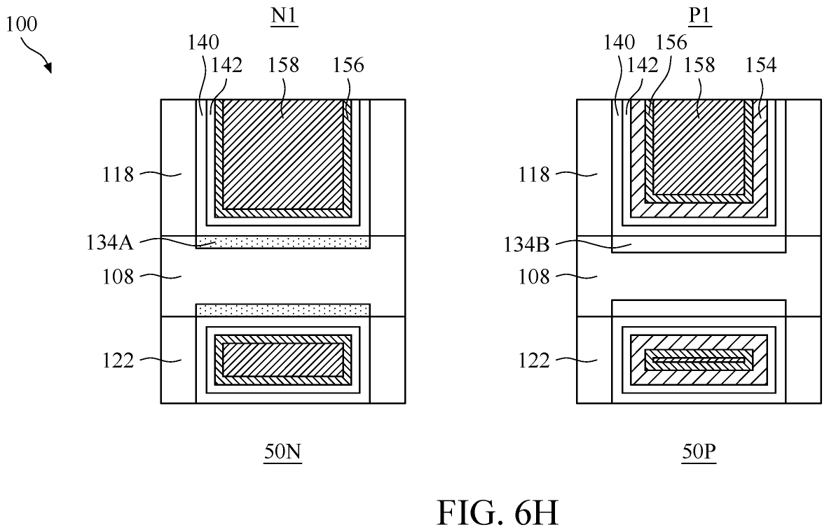

FIGS. 6A through 6H are cross-sectional views illustrating an incorporation of dopants into an interfacial layer and the formation of final gate stacks at various intermediate stages, in accordance with some embodiments of the disclosure. FIGS. 6A through 6H illustrate a portion of a semiconductor structure 100 corresponding to area R of FIG. 2D-1. The embodiments of FIGS. 6A through 6H are similar to the embodiments of FIGS. 3A through 3L except that the formation of the capping layers 144 and 146 and the anneal process 1000 are performed after the incorporation of dopants into an interfacial layer.

FIG. 6A illustrates the semiconductor structure 100 after the formation of the interfacial layer 134, the first high-k dielectric layer 140 and the second high-k dielectric layer 142, in accordance with some embodiments.

After the interfacial layer 134 is formed on the nanostructures 108, the first high-k dielectric layer 140 and the second high-k dielectric layer 142 are sequentially formed on the interfacial layer 134 in the device region 50N and the device region 50P, as shown in FIGS. 6A, in accordance with some embodiments.

FIG. 6B illustrates the semiconductor structure 100 after the formation of the patterned hard mask layer 148B, in accordance with some embodiments.

The patterned hard mask layer 148B is formed to cover the second high-k dielectric layer 142 in the device region 50P, as shown in FIG. 6B, in accordance with some embodiments.

FIG. 6C illustrates the semiconductor structure 100 after the plasma treatment 1050, in accordance with some embodiments.

The plasma treatment 1050 is performed on the semiconductor structure 100, as shown in FIG. 6C, in accordance with some embodiments. The nitrogen radicals are introduced onto and adsorbed onto the exposed surface of the second high-k dielectric layer 142 in the device region 50N and the exposed surface of the patterned hard mask layer 148B in the device region 50P, in accordance with some embodiments.

FIG. 6D illustrates the semiconductor structure 100 after an etching process, in accordance with some embodiments.

An etching process is performed to remove the patterned hard mask layer 148B from the device region 50P, thereby exposing the second high-k dielectric layer 142 in the device region 50P, as shown in FIG. 6D, in accordance with some embodiments.

FIG. 6E illustrates the semiconductor structure 100 after the anneal process 1100, in accordance with some embodiments.

The anneal process 1100 is performed on the semiconductor structure 100, as shown in FIG. 6E, in accordance with some embodiments. In some embodiments, the anneal process 1100 drives the nitrogen radicals from the surface of the second high-k dielectric layer 142 into the interfacial layer 134 in the device region 50N.

The interfacial layer 134 in the device region 50N is doped with nitrogen to form the nitrogen-doped interfacial layer 134A, and the interfacial layer 134 in the device region 50P regrows to form the thickened interfacial layer 134B, as shown in FIG. 6E, in accordance with some embodiments.

FIG. 6F illustrates the semiconductor structure 100 after the formation of the first capping layer 144 and the second capping layer 146, in accordance with some embodiments. The first capping layer 144 and the second capping layer 146 are sequentially formed on and around the second high-k dielectric layer 142 in the device region 50N and the device region 50P, as shown in FIG. 6F, in accordance with some embodiments.

FIG. 6G illustrates the semiconductor structure 100 after the anneal process 1000, in accordance with some embodiments.

The anneal process 1000 is performed on the semiconductor structure 100, in accordance with some embodiments. After the anneal process 1000, the capping layers 144 and 146 are removed using one or more etching processes, in accordance with some embodiments.

Metal (e.g., titanium) from the first capping layer 144 (e.g., TiN) may diffuse into the second high-k dielectric layer 142 during the thermal process (e.g., the anneal process 1000), thereby forming an intermixing layer. The intermixing layer may serve as a leakage path between the gate electrode material and the channel. In accordance with some embodiments of the present disclosure, the formation of the capping layers 144 and 146 and the anneal process 1000 are performed after the incorporation of nitrogen into the interfacial layer 134, which may reduce the thermal budget contributing the growth of the intermixing layer. Therefore, off-state gate leakage of the resulting semiconductor device may improve (e.g., lower).

In addition, the thermal budget contributing to drive nitrogen increases, which is helpful in further reducing the capacitance equivalent thickness of the n-type transistor N1, in accordance with some embodiments. Therefore, the performance (e.g., DC performance and RO performance) of the resulting semiconductor device may improve.

FIG. 6H illustrates the semiconductor structure 100 after the formation of the p-type work function layer 154, the n-type work function layer 156 and the gate metal fill layer 158, in accordance with some embodiments.

The steps discussed above in FIGS. 3J to 3L are performed, thereby forming the p-type work function layer 154, the n-type work function layer 156 and the gate metal fill layer 158, as shown in FIG. 6H, in accordance with some embodiments.

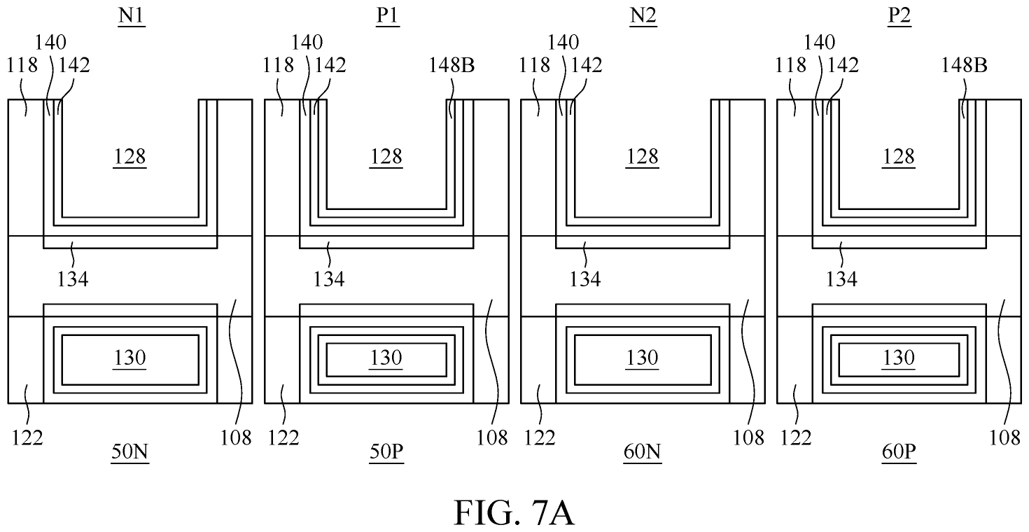

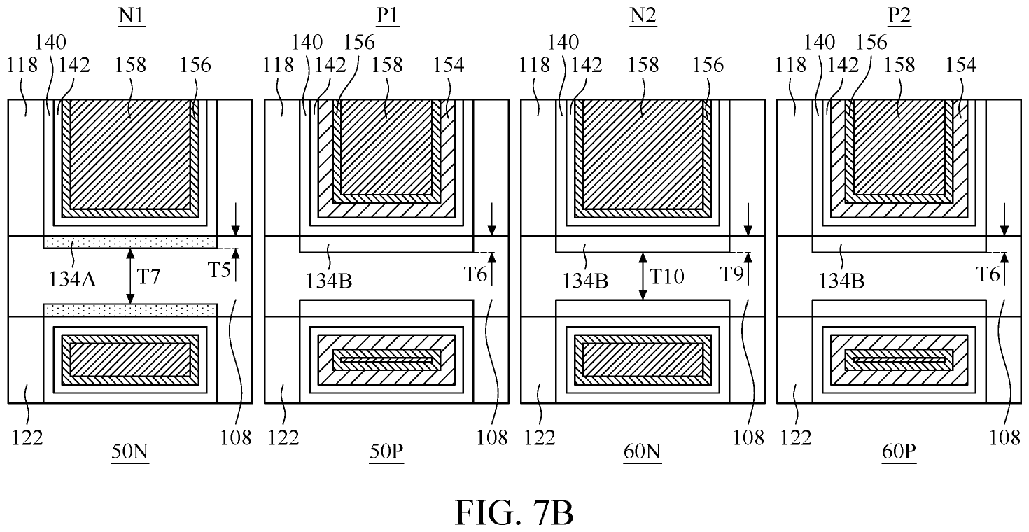

FIGS. 7A and 7B are cross-sectional views illustrating an incorporation of dopants into an interfacial layer and the formation of final gate stacks at various intermediate stages, in accordance with some embodiments of the disclosure. FIGS. 7A and 7B illustrate a portion of a semiconductor structure 100 corresponding to area R of FIG. 2D-1. The embodiments of FIGS. 7A and 7B are similar to the embodiments of FIGS. 3A through 3L except that the semiconductor structure 100 further includes memory device regions 60N and 60P.

FIG. 7A illustrates the semiconductor structure 100 after the formation of the patterned hard mask layer 148B, in accordance with some embodiments.

The substrate 102 includes device regions 50N and 50P and device regions 60N and 60P, as shown in FIG. 7A, in accordance with some embodiments. In some embodiments, the device regions 50N and 50P are defined in a logic device region of the substrate 102, and the device regions 60N and 60P are defined in a memory device region of the substrate 102. In some embodiments, an n-type transistor N2 is predetermined to be formed on the nanostructures 108 in the memory device region 60N and has a threshold voltage Vn2. Here, 0<Vn2. In some embodiments, a p-type transistor P2 is predetermined to be formed on the nanostructures 108 in the memory device region 60P and has a threshold voltage Vp2. Here, Vp2<0.

In some embodiments, the n-type transistors N1 and N2 are n-channel nanostructure transistors, and the p-type transistors P1 and P2 are p-channel nanostructure transistors. In some embodiments, the n-type transistor N2 may serve as the pull-down transistor and the pass-gate transistor of an SRAM (static random access memory) device, and the p-type transistor P2 may serve as the pull-up transistor of the SRAM device.

Continuous from FIG. 3F, a patterned hard mask layer 148B is formed to cover the second high-k dielectric layer 142 in the device regions 50P, 60N and 60P, as shown in FIG. 6A, in accordance with some embodiments. The formation of the patterned hard mask layer 148B may be the same as to similar to the formation of the patterned hard mask layer 148B described above in FIGS. 3E and 3F, in accordance with some embodiments.

FIG. 7B illustrates the semiconductor structure 100 after the incorporation of nitrogen into the interfacial layer 134, and the formation of the p-type work function layer 154, the n-type work function layer 156 and the gate metal fill layer 158, in accordance with some embodiments.

The interfacial layer 134 in the device region 50N is doped with nitrogen, as shown in FIG. 7B, in accordance with some embodiments. In specific, the plasma treatment 1050 is performed on the semiconductor structure 100, so that the nitrogen radicals are adsorbed onto the exposed surface of the second high-k dielectric layer 142 in the device region 50N, in accordance with some embodiments. The patterned hard mask layer 148B is then removed, in accordance with some embodiments. The anneal process 1100 is then performed on the semiconductor structure 100 to drive the nitrogen radicals from the surface of the second high-k dielectric layer 142 into the interfacial layer 134 in the device region 50N.

The interfacial layer 134 in the device region 50N is doped with nitrogen to form the nitrogen-doped interfacial layer 134A, and the interfacial layers 134 in the device regions 50P, 60N and 60P regrow to form thickened interfacial layers 134B, as shown in FIG. 7B, in accordance with some embodiments. In some embodiments, the thickened interfacial layer 134B of the n-type transistor N2 has a thickness T9 that is greater than the thickness T5 of the nitrogen-doped interfacial layer 134A of the n-type transistor N1 and in a range from 5.5 Å to about 16.5 Å.

The thickness T7 of the nanostructures 108 in the device region 50N is thicker than the thickness T10 of the nanostructures 108 in the device region 60N, in accordance with some embodiments. In some embodiments, the thickened interfacial layer 134B is non-doped, and thus has a lower dielectric constant than the dielectric constant of the nitrogen-doped interfacial layer 134A, e.g., being approximately 3.9.

In some embodiments, the capacitance equivalent thickness of the n-type transistor N2 is thicker than the capacitance equivalent thickness of the n-type transistor N1. As a result, the threshold voltage Vn2 of the n-type transistor N2 is higher than the threshold voltage Vn1 of the n-type transistor N1.

The steps discussed above in FIGS. 3J to 3L are performed, thereby forming the p-type work function layer 154, the n-type work function layer 156 and the gate metal fill layer 158, as shown in FIG. 7B, in accordance with some embodiments.

In some embodiments, the logic device including the transistors N1 and P1 may focus more on performance, e.g., higher speed, while the SRAM device including the transistors N2 and P2 may focus more on reliability, e.g., lower gate leakage. Therefore, the n-type transistor N2 having a thickened interfacial layer 134B may improve off-state gate leakage of the resulting semiconductor device, in accordance with some embodiments.

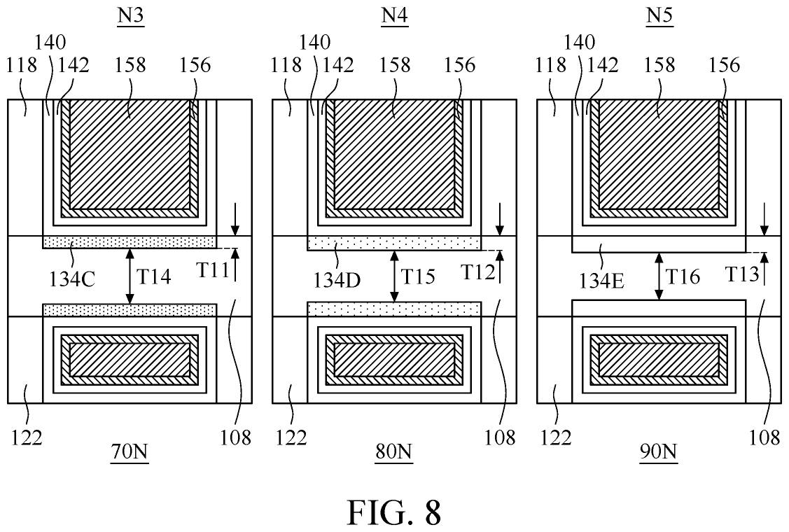

FIG. 8 illustrate a portion of a semiconductor structure 100 having for various types of transistors having different threshold voltages, in accordance with some embodiments of the disclosure.

The substrate 102 includes device regions 70N, 80N and 90N, as shown in FIG. 8, in accordance with some embodiments. In some embodiments, an n-type transistor N3 is predetermined to be formed on the nanostructures 108 in the device region 70N and has a threshold voltage Vn1 (e.g., extremely low voltage or ultra-low voltage); an n-type transistor N4 is predetermined to be formed on the nanostructures 108 in the device region 80N and has a threshold voltage Vn3 (e.g., low voltage); and an n-type transistor N5 is predetermined to be formed on the nanostructures 108 in the device region 90N and has a threshold voltage Vn4 (e.g., standard voltage). Here, 0<Vn1<Vn3<Vn4.

In some embodiments, the n-type transistor N3 includes a first nitrogen-doped interfacial layer 134C, the n-type transistor N4 includes a second nitrogen-doped interfacial layer 134D, and the n-type transistor N5 includes a thickened interfacial layer 134E. Each of the n-type transistors N3, N4 and N5 also includes high-k dielectric layers 140 and 142 on the interfacial layer 134C, 134D or 134E, the n-type work function layer 156 on the high-k dielectric layer 142, and the gate metal fill layer 158 on the n-type work function layer 142.

In some embodiments, the average nitrogen concentration of the nitrogen-doped interfacial layer 134C of the n-type transistor N3 is greater than the average nitrogen concentration of the nitrogen-doped interfacial layer 134D of the n-type transistor N4. In some embodiments, the thickened interfacial layer 134E of the n-type transistor N5 is not doped with nitrogen.

In some embodiments, the thickness T11 of the nitrogen-doped interfacial layer 134C is thinner than the thickness T12 of the nitrogen-doped interfacial layer 134D, and the thickness T12 of the nitrogen-doped interfacial layer 134D is thinner than the thickness T13 of the thickened interfacial layer 134E.

As a result, the capacitance equivalent thickness of the n-type transistor N3 is thinner than the capacitance equivalent thickness of the n-type transistor N4, and the capacitance equivalent thickness of the n-type transistor N4 is thinner than the capacitance equivalent thickness of the n-type transistor N5, in accordance with some embodiments.

The formation of the interfacial layer 134C, 134D and 134E may include two patterning processes and two incorporations of nitrogen. For example, after removing the capping layers 144 and 146, a first patterned hard mask layer (e.g., the patterned hard mask layer 148B as described above in FIG. 3F) is formed to cover the device regions 80N and 90N. A first incorporation of nitrogen (e.g., the plasma treatment 1050 and the anneal process 1100 as described above in FIGS. 3G-3I) is performed to drive nitrogen into the interfacial layer 134 in the device region 70N.

Afterward, a second patterned hard mask layer (e.g., the patterned hard mask layer 148B as described above in FIG. 3F) is formed to cover the device region 90N, and a second incorporation of nitrogen (e.g., the plasma treatment 1050 and the anneal process 1100 as described above in FIGS. 3G-3I) is performed to drive nitrogen into the interfacial layers 134 in the device regions 70N and 80N. Therefore, the interfacial layer 134 in the device region 70N is doped with nitrogen twice, and the interfacial layer 134 in the device region 80N is doped with nitrogen once, in accordance with some embodiments.

In addition, the interfacial layer 134 in the device region 90N undergoes regrowth twice, and the interfacial layer 134 in the device region 80N undergoes regrowth once, in accordance with some embodiments. As a result, in some embodiments, the thickness T14 of the nanostructures 108 in the device region 70N is thicker than the thickness T15 of the nanostructures 108 in the device region 80N, and the thickness T15 of the nanostructures 108 in the device region 80N is thicker than the thickness T16 of the nanostructures 108 in the device region 90N.

As described above, the aspect of the present disclosure is directed to a semiconductor structure having various devices with different threshold voltages. The semiconductor structure includes an n-type transistor N1 and a p-type transistor P1. An incorporation of nitrogen is performed to drive nitrogen into the interfacial layer 134 of the n-type transistor N1, thereby thinning down the capacitance equivalent thickness of the n-type transistor N1. The interfacial layer 134 of the p-type transistor P1 remains undoped. Therefore, the performance (e.g., DC performance and RO performance) of the resulting semiconductor device may improve.

Embodiments of a semiconductor structure and the method for forming the same may be provided. The method for forming a semiconductor structure may include forming a patterned mask layer to cover a p-type device, and driving nitrogen into an interfacial layer of an n-type device. As a result, for the n-type device, the gate control capability over the channel may enhance. Therefore, the performance of the resulting semiconductor device may improve.

In some embodiments, a method for forming a semiconductor structure is provided. The method includes forming a first nanostructure and a second nanostructure over a substrate, forming a first interfacial layer on the first nanostructure and a second interfacial layer on the second nanostructure, forming a first gate dielectric layer on the first interfacial layer and a second gate dielectric layer on the second interfacial layer, forming a patterned mask layer on the second gate dielectric layer while exposing the first gate dielectric layer, and driving nitrogen into the first interfacial layer, thereby forming a nitrogen-doped interfacial layer.

In some embodiments, a method for forming a semiconductor structure is provided. The method includes forming a plurality of first nanostructures over a substrate, forming a first interfacial layer around the plurality of first nanostructures, forming a first high-k dielectric layer around the first interfacial layer, treating a surface of the first high-k dielectric layer so that a dopant adsorbs onto the surface of the first high-k dielectric layer, annealing the substrate to drive the dopant into the first interfacial layer; and forming a first work function layer around the first high-k dielectric layer.

In some embodiments, a semiconductor structure is provided. The semiconductor structure includes an n-type transistor and a p-type transistor adjacent to the first transistor. The n-type transistor includes a first nanostructure, a first interfacial layer surrounding the first nanostructure, and a first high-k dielectric layer surrounding the first nanostructure. The p-type transistor includes a second nanostructure, a second interfacial layer surrounding the second nanostructure, and a second high-k dielectric layer surrounding the second interfacial layer. The first interfacial layer is thinner than the second interfacial layer, and a first capacitance equivalent thickness of the n-type transistor is thinner than a second capacitance equivalent thickness of the p-type transistor.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor structure, comprising:
forming a first nanostructure and a second nanostructure over a substrate;
forming a first interfacial layer on the first nanostructure and a second interfacial layer on the second nanostructure;
forming a first gate dielectric layer on the first interfacial layer and a second gate dielectric layer on the second interfacial layer;
forming a patterned mask layer on the second gate dielectric layer while exposing the first gate dielectric layer; and
driving nitrogen into the first interfacial layer, thereby forming a nitrogen-doped interfacial layer.

2. The method for forming the semiconductor structure as claimed in claim 1, wherein diffusing nitrogen into the first interfacial layer through the first gate dielectric layer comprises:
plasma treating the first gate dielectric layer and the patterned mask layer using a nitrogen-containing gas; and
annealing the substrate so that nitrogen diffuses through the first gate dielectric layer into the first interfacial layer.

3. The method for forming the semiconductor structure as claimed in claim 2, wherein plasma treating the first gate dielectric layer and the patterned mask layer with the nitrogen radical is performed at a first temperature, and annealing the substrate is performed at a second temperature that is greater than the first temperature.

4. The method for forming the semiconductor structure as claimed in claim 2, further comprising:
removing the patterned mask layer to expose the second gate dielectric layer after plasma treating and before annealing the substrate.

5. The method for forming the semiconductor structure as claimed in claim 2, wherein the second interfacial layer regrows in the step of annealing the substrate to form a thickened interfacial layer that is thicker than the nitrogen-doped interfacial layer.

6. The method for forming the semiconductor structure as claimed in claim 2, wherein the nitrogen-containing gas is activated to form the nitrogen radical, and the nitrogen radical is adsorbed onto a surface of the first gate dielectric layer.

7. The method for forming the semiconductor structure as claimed in claim 1, further comprising:
forming a first gate electrode layer on the first gate dielectric layer, wherein the first gate electrode layer, the first gate dielectric layer, the nitrogen-doped interfacial layer and the first nanostructure form a first transistor; and
forming a second gate electrode layer on the first gate dielectric layer, wherein the second gate electrode layer, the second gate dielectric layer, the second interfacial layer and the second nanostructure form a second transistor,
wherein the first transistor has a first capacitance equivalent thickness, and the second transistor has a second capacitance equivalent thickness that is thinner than the first capacitance equivalent thickness.

8. The method for forming the semiconductor structure as claimed in claim 7, wherein the first transistor has a first threshold voltage greater than zero, and the second transistor has a second threshold voltage greater than the first threshold voltage.

9. The method for forming the semiconductor structure as claimed in claim 1, wherein the first nanostructure is formed in a logic device region of the substrate, and the second nanostructure is formed in a memory device region of the substrate.

10. A method for forming a semiconductor structure, comprising:
forming a plurality of first nanostructures over a substrate;
forming a first interfacial layer around the plurality of first nanostructures;
forming a first high-k dielectric layer around the first interfacial layer;
treating a surface of the first high-k dielectric layer so that a dopant adsorbs onto the surface of the first high-k dielectric layer;
annealing the substrate to drive the dopant into the first interfacial layer; and
forming a first work function layer around the first high-k dielectric layer.

11. The method for forming the semiconductor structure as claimed in claim 10, further comprising, after annealing the substrate:
forming a first capping layer around the first high-k dielectric layer;
forming a second capping layer around the first capping layer, wherein the second capping layer and the first capping layer are made of different materials; and
removing the second capping layer and the first capping layer to expose the first high-k dielectric layer.

12. The method for forming the semiconductor structure as claimed in claim 10, further comprising:
forming a second high-k dielectric layer around the first interfacial layer, wherein the first high-k dielectric layer is formed around the second high-k dielectric layer, and a dielectric constant of the first high-k dielectric layer is greater than a dielectric constant of the second high-k dielectric layer.

13. The method for forming the semiconductor structure as claimed in claim 12, wherein the dopant is nitrogen, and after annealing the substrate, a nitrogen concentration of the interfacial layer increases from an interior of the interfacial layer to an interface between the interfacial layer and the second high-k dielectric layer.

14. The method for forming the semiconductor structure as claimed in claim 10, wherein the dopant is driven into the first interfacial layer to form a doped interfacial layer, and a dielectric constant of the doped interfacial layer is greater than a dielectric constant of the first interfacial layer.

15. The method for forming the semiconductor structure as claimed in claim 10, further comprising:
forming a plurality of second nanostructures laterally spaced apart from the plurality of first nanostructures;
forming a second interfacial layer around the plurality of second nanostructures;
forming a second high-k dielectric layer around the second interfacial layer;
forming a patterned mask layer around the second high-k dielectric layer;
treating a surface of the patterned mask layer;
removing the patterned mask layer before annealing the substrate; and
forming a second work function layer around the second high-k dielectric layer.

16. A semiconductor structure, comprising:
an n-type transistor comprising a first nanostructure, a first interfacial layer surrounding the first nanostructure, and a first high-k dielectric layer surrounding the first nanostructure; and
a p-type transistor adjacent to the first transistor, comprising a second nanostructure, a second interfacial layer surrounding the second nanostructure, and a second high-k dielectric layer surrounding the second interfacial layer, wherein the first interfacial layer is thinner than the second interfacial layer.

17. The semiconductor structure as claimed in claim 16, wherein a nitrogen concentration of the first interfacial layer is higher than a nitrogen concentration of the second interfacial layer.

18. The semiconductor structure as claimed in claim 16, wherein a first capacitance equivalent thickness of the n-type transistor is thinner than a second capacitance equivalent thickness of the p-type transistor.

19. The semiconductor structure as claimed in claim 16, wherein a dielectric constant of the first interfacial layer is greater than a dielectric constant of the second interfacial layer.

20. The semiconductor structure as claimed in claim 19, further comprising:
a second n-type transistor comprising a third nanostructure, a third interfacial layer surrounding the first nanostructure, and a third high-k dielectric layer surrounding the third nanostructure, wherein the first interfacial layer is thinner than the third interfacial layer.
